(19) United States
(12) Patent Application Publication
(10) Pub. No.: US 2025/0308859 A1
(43) Pub. Date: Oct. 2, 2025

(54) EDGE RING SYSTEM AND CORRESPONDING MIDDLE, EDGE, MOVING, STATIC AND BOTTOM RINGS

(71) Applicant: LAM RESEARCH CORPORATION, Fremont, CA (US)

(72) Inventors: Nicholas John CELESTE, Oakland, CA (US); Sarath RAMADURGAM, Fremont, CA (US)

(21) Appl. No.: 18/864,365

(22) PCT Filed: May 11, 2023
(86) PCT No.: PCT/US2023/021828

§ 371 Date: Nov. 8, 2024

Related U.S. Application Data
(60) Provisional application No. 63/342,826, filed on May 17, 2022.
(60) Provisional application No. 63/458,542, filed on Apr. 11, 2023.

(51) Int. Cl. H01J 37/32

(52) U.S. Cl. CPC H01J 37/32642

(57) ABSTRACT

An edge ring system for a substrate processing chamber includes a middle ring configured for arrangement around a substrate support. The edge ring system includes an outer ring portion, an inner ring portion, N arcuate openings arranged between the outer ring portion and the inner ring portion, where N is an integer greater than 1, N bridges connecting the outer ring portion and the inner ring portion between the N arcuate openings, and an annular cavity arranged on a radially inner surface of the outer ring portion. A cover ring is arranged in the annular cavity. A top edge ring is arranged above the middle ring between the cover ring and the inner ring portion and above the N arcuate openings and the N bridges of the middle ring.

### CROSS-REFERENCE TO RELATED APPLICATIONS

This application claims the benefit of U.S. Provisional Application No. 63/342,826 filed on May 17, 2022 and U.S. Provisional Application No. 63/458,542 filed on Apr. 11, 2023. The entire disclosures of each of the above applications are incorporated herein by reference.

### FIELD

The present disclosure relates to a self-centering edge ring for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems perform treatments on substrates such as semiconductor wafers. Examples of substrate treatments include deposition, ashing, etching, cleaning, and/or other processes. Process gas mixtures may be supplied to the processing chamber to treat the substrate. Plasma may be used to ignite the gases to enhance chemical reactions.

The substrate is arranged on a substrate support during treatment. An edge ring that includes an annular body is arranged around and adjacent to a radially outer edge of the substrate. The edge ring may be used to shape or focus the plasma onto the substrate.

### SUMMARY

An edge ring system for a substrate processing chamber includes a middle ring including an outer ring portion and an inner ring portion and an edge ring configured to be supported on the middle ring between the outer ring portion and the inner ring portion. An outer diameter of a lower surface of the edge ring has a first chamfer defining a downward and outward facing chamfered surface. An inner diameter of the outer ring portion has a second chamfer defining an upward and inward facing chamfered surface. At least one of the first chamfer and the second chamfer is configured to align the edge ring within the outer ring portion and the inner ring portion of the middle ring.

In other features, the middle ring is further configured to align the edge ring with a moving ring such that the edge ring is centered relative to a substrate being processed in the substrate processing chamber. The inner ring portion of the middle ring is generally “L”-shaped and has a ledge extending radially outward toward the outer ring portion. The edge ring is configured to be at least partially supported on the ledge of the inner ring portion. The edge ring includes a rim that extends downward from the lower surface at an inner diameter of the edge ring and the rim is configured to be supported on the ledge of the inner ring portion. The inner ring portion is configured to force the edge ring into a centered position relative to the middle ring. An interface between the edge ring and the inner ring portion defines a serpentine path.

In other features, the edge ring is supported entirely within an inner diameter and an outer diameter of the middle ring. The middle ring includes a plurality of bridges connecting the inner ring portion to the outer ring portion. The middle ring includes six of the bridges. The middle ring includes a plurality of gaps defined between the plurality of bridges. The edge ring system further includes a moving ring configured to be raised and lowered relative to the middle ring. The moving ring is configured to contact the lower surface of the edge ring through the plurality of gaps. The moving ring includes raised portions that extend upward through the plurality of gaps to contact the lower surface of the edge ring. The moving ring includes a static ring portion and a moving ring portion located radially inward of the static ring portion, and wherein the moving ring portion is configured to be raised and lowered.

In other features, a lower surface of the outer ring portion of the middle ring includes an annular groove. The edge ring system further includes a bottom ring and the middle ring is supported on the bottom ring. The bottom ring includes an annular rim that extends upward from an upper surface of the bottom ring into the annular groove.

An edge ring system for a substrate processing chamber includes a middle ring including an outer ring portion and an inner ring portion and an edge ring supported on the middle ring between the outer ring portion and the inner ring portion. The edge ring is supported entirely within an inner diameter and an outer diameter of the middle ring and at least one of the outer ring portion and the inner ring portion is configured to force the edge ring into the centered position relative to the middle ring. A moving ring is arranged below the middle ring. The moving ring is configured to be raised and lowered to contact and selectively raise and lower the edge ring.

In other features, the middle ring includes a plurality of bridges connecting the inner ring portion to the outer ring portion and a plurality of gaps defined between the plurality of bridges. The moving ring is configured to contact a lower surface of the edge ring through the plurality of gaps. The moving ring includes raised portions that extend upward through the plurality of gaps to contact the lower surface of the edge ring.

An edge ring system for a substrate processing chamber includes a middle ring configured for arrangement around a substrate support and including an outer ring portion, an inner ring portion, N arcuate openings arranged between the outer ring portion and the inner ring portion, where N is an integer greater than 1, N bridges connecting the outer ring portion and the inner ring portion between the N arcuate openings, and an annular cavity arranged on a radially inner surface of the outer ring portion. A cover ring is arranged in the annular cavity. A top edge ring is arranged above the middle ring between the cover ring and the inner ring portion and above the N arcuate openings and the N bridges of the middle ring.

In other features, a moving ring including N upper portions having an arcuate shape configured to align with and pass through the N arcuate openings. The top edge ring rests on the N upper portions. The N upper portions of the moving ring are configured to bias a bottom surface of the top edge ring through the N arcuate openings of the middle ring to raise the top edge ring relative to the cover ring.

In other features, a first lift pin is configured to selectively raise the moving ring and the top edge ring upwardly relative to the cover ring and the middle ring. A second lift pin is configured to selectively bias the middle ring, the top edge ring, and the cover ring relative to the moving ring.

In other features, the top edge ring has a “C”-shaped cross-section defining an inner annular projection extending downwardly and an outer annular projection extending downwardly and a cavity arranged between the inner annular projection and the outer annular projection. The N bridges include a projection extending upwardly towards a lower surface of the top edge ring. The cover ring has an inverted “L”-shaped cross-section.

In other features, a radially inner side of the cover ring includes a radially inner surface and an arcuate surface. The radially inner surface of the cover ring is located radially inwardly from a radially outer surface of an upper portion of the moving ring. A radially outer surface of the top edge ring is arranged below and radially outside of the radially inner surface of the cover ring. An upper and radially outer edge of the top edge ring has an arcuate shape corresponding to the arcuate surface of the cover ring.

In other features, at least one of the N bridges of the middle ring includes one of a projection and a cavity and a radially inner edge of the outer annular projection of the top edge ring includes the other of a cavity and a projection. The one of the projection and the cavity of the at least one of the N bridges of the middle ring is received in the other of the cavity and the projection on the radially inner edge of the outer annular projection of the top edge ring. A static ring configured for arrangement around the substrate support below the middle ring.

In other features, the static ring includes a projection extending radially inwardly from a lower portion of a radially inner surface of the static ring, wherein the moving ring is arranged above the projection of the static ring and radially inside of the static ring. In other features, the moving ring includes a first plurality of projections extending radially outwardly from the moving ring. A bottom surface of the first plurality of projections includes a groove including opposed inclined surfaces extending in a radial direction.

In other features, the moving ring includes a second plurality of projections extending radially outwardly from the moving ring and a bore extending in an axial direction through the second plurality of projections. The static ring includes a first plurality of cavities extending in a radially inward direction from a radially inner surface of the static ring and configured to provide clearance for a first plurality of projections of the moving ring. The static ring includes a second plurality of cavities extending in a radially inward direction from a radially inner surface of the static ring and configured to provide clearance for a second plurality of projections of the moving ring. A bottom edge ring includes a first annular rim extending inwardly from a radially inner surface of the bottom edge ring and an annular body arranged around the static ring.

In other features, the bottom edge ring further includes a second annular rim extending upwardly from an upper surface of the bottom edge ring. The middle ring includes an annular groove configured to receive the second annular rim of the bottom edge ring. A gap is defined between a bottom surface of the middle ring and an upper surface of the bottom edge ring. A bottom surface of the first annular rim rests on the static ring. The first annular rim includes a first plurality of recesses extending in a radially inward direction to provide clearance for a first plurality of projections of the moving ring. The first annular rim includes a second plurality of cavities extending in a radially inward direction from a radially inner surface of the static ring and configured to provide clearance for a second plurality of projections of the moving ring.

In other features, the middle ring comprises quartz. The cover ring comprises quartz. The top edge ring comprises silicon carbide. The moving ring comprises a silicon substrate with an electroplated aluminum outer layer. The static ring comprises a silicon substrate with one of a coating including perfluoroalkoxy alkane (PFA) and an electroplated aluminum outer layer.

A middle ring for a substrate processing chamber includes an outer ring portion, an inner ring portion, N bridges connecting the outer ring portion to the inner ring portion, where N is an integer greater than 1, and N arcuate openings arranged between the N bridges, respectively, and between the outer ring portion and the inner ring portion.

In other features, an annular cavity arranged on an upper, radially inner surface of the outer ring portion. At least one of the N bridges includes one of a projection and a cavity configured to orient the middle ring relative to another edge ring. The one of the projection and the cavity is arranged on a radially outer surface of the at least one of the N bridges. The middle ring comprises quartz. G alignment portions arranged on a bottom surface of the outer ring portion, where G is an integer greater than two. The G alignment portions include a planar surface arranged between opposed inclined surfaces extending in a radial direction.

In other features, the G alignment portions are configured to self-center the middle ring on lift pins. Opposite ends of the N arcuate openings are rounded. Circumferential side surfaces of the N bridges are rounded to define rounded ends of the N arcuate openings. An annular groove arranged on a bottom surface of the outer ring portion.

In other features, G alignment portions arranged on a bottom surface of the outer ring portion and including a planar surface arranged between opposed inclined surfaces extending in a radially outward direction, where G is an integer greater than two. An annular groove is arranged on a bottom surface of the outer ring portion and located radially outside of the G alignment portions. The middle ring comprises quartz.

A top edge ring for a substrate processing system includes an annular body having a “C”-shaped cross-section. An inner annular projection extends downwardly from a radially inner surface of the annular body. An outer annular projection extends downwardly from a radially inner surface of the annular body. A cavity is arranged between the inner annular projection and the outer annular projection.

In other features, the top edge ring comprises silicon carbide. A projection is arranged on one of a radially inner surface of the outer annular projection and radially outer surface of the inner annular projection. The projection is configured to orient the top edge ring relative to another edge ring.

In other features, the projection has a semicircular shape. A cavity is arranged on one of a radially inner surface of the outer annular projection and a radially outer surface of the inner annular projection. The cavity is configured to orient the top edge ring relative to another edge ring. The cavity has a semicircular shape.

In other features, the top edge ring comprises silicon carbide.

A moving ring for a substrate processing system includes an annular body, N upper portions arranged on a top edge of the annular body and having an arcuate shape, N gaps arranged between the N upper portions, P first projections arranged on a radially outer surface of the annular body, where P is an integer greater than two, and P grooves arranged on a bottom surface of the P first projections and configured to self-center the moving ring when the P self-centering portions are biased by P lift pins.

In other features, the P first projections have a “V”-shape. The P grooves have a “V”-shape including opposed inclined surfaces extending in a radial direction. R first projections arranged on an outer surface, where R is an integer greater than two. R bores passing through R of the N upper portions and the R first projections. The N upper portions are rounded at opposite circumferential ends thereof. The moving ring comprises a silicon substrate with an electroplated aluminum outer layer.

A static ring for an edge ring system of a substrate processing system includes an annular body; an annular rim extending radially inwardly from a lower end of the annular body; P first cavities arranged on a radially inner surface of the annular body, where P is an integer greater than two; and P bores passing through the annular rim in the P first cavities.

In other features, the P first cavities have a rounded “V”-shape. R second cavities arranged on a radially inner surface of the annular body, where R is an integer greater than two. The R second cavities have a rounded “V”-shape. P=3 and the P first cavities are spaced at 120° intervals.

In other features, R second cavities are arranged on a radially inner surface of the annular body, wherein R is an integer greater than two, and wherein the R second cavities are arranged between the P first cavities. P=3, R=3, the P first cavities are spaced at 120° intervals, and the R second cavities are spaced at 120° intervals and are evenly spaced between the P first cavities. S cavities extending axially into a bottom surface of the annular body, where S is an integer greater than two. S plug arranged in the S cavities. The static ring comprises a silicon substrate with one of a coating including perfluoroalkoxy alkane (PFA) and an electroplated aluminum outer layer.

A bottom edge ring for an edge ring system of a substrate processing system includes an annular body, an annular rim extending radially inwardly from an upper end of the annular body, and P first recesses arranged on a radially inner edge of the annular rim, where P is an integer greater than two.

In other features, the P first recesses are spaced 360°/P and have a rounded “V”-shape. R second recesses arranged on the radially inner edge of the annular rim, where R is an integer greater than two. The R second recesses are spaced 360°/R and have a rounded “V”-shape. P=3 and the P first recesses are spaced at 120° intervals. R second recesses arranged on a radially inner surface of the annular body, where R is an integer greater than two, wherein the R second recesses are arranged between the P first recesses. P=3, R=3, the P first recesses are spaced at 120° intervals, and the R second recesses are spaced at 120° intervals and are evenly spaced between the P first recesses.

In other features, S bores extend axially through the annular body, where S is an integer greater than 2. T bores extending axially into the annular body, where T is an integer greater than 2. T plugs arranged in the T bores.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system including a self-centering edge ring according to the present disclosure;

FIGS. 2A and 2B are cross-sectional views of an example edge ring system with an edge ring and a middle ring in a raised position according to the present disclosure;

FIG. 2C is a cross-sectional view of the edge ring system of FIGS. 2A and 2B with the edge ring in a raised position and the middle ring in a lowered position according to the present disclosure;

FIG. 2D is an isometric view of the middle ring of FIGS. 2A, 2B, and 2C;

FIG. 2E is a plan view of the middle ring of FIGS. 2A, 2B, 2C, and 2D;

FIG. 2F is a plan view of the moving ring of FIGS. 2A, 2B, and 2C;

FIG. 2G is an isometric view of a bottom of the edge ring of FIGS. 2A, 2B, and 2C;

FIG. 2H is another isometric view of the bottom of the edge ring of FIG. 2G;

FIG. 3A is a first cross-sectional view of an example edge ring system including a moving ring assembly according to the present disclosure;

FIG. 3B is a first cross-sectional view of an example edge ring system including a moving ring assembly according to the present disclosure;

FIG. 4A is a side cross-sectional view of another example of an edge ring system showing the top ring and the moving ring in a lowered position according to the present disclosure;

FIG. 4B is a side cross-sectional view of the edge ring system of FIG. 4A with the top ring and the moving ring in a raised position according to the present disclosure;

FIG. 5A is a side cross-sectional view of the edge ring system of FIG. 4A showing the cover ring, the top ring, and the middle ring in a lowered position according to the present disclosure;

FIG. 5B is a side cross-sectional view of the edge ring system of FIG. 4A showing the cover ring, the top ring, and the middle ring in a raised position according to the present disclosure;

FIG. 6A is a side cross-sectional view of the edge ring system of FIG. 4A showing the top ring and the moving ring in a lowered position according to the present disclosure;

FIG. 6B is a side cross-sectional view of the edge ring system of FIG. 4A with the top ring and the moving ring in a raised position according to the present disclosure;

FIG. 7A is a side cross-sectional view of the edge ring system of FIG. 4A showing the top ring and the moving ring in a lowered position according to the present disclosure;

FIG. 7B is a side cross-sectional view of the edge ring system of FIG. 4A with the top ring and the moving ring in a raised position according to the present disclosure;

FIGS. 8A and 8B are plan and bottom views, respectively, of an example of the middle ring of FIG. 4A according to the present disclosure;

FIG. 9A and 9C are enlarged partial plan views of examples of the middle ring of FIG. 8A according to the present disclosure;

FIG. 9B and 9D are enlarged partial bottom views of examples of the top ring of FIG. 4A according to the present disclosure;

FIGS. 9E and 9F are side cross-sectional views showing axial projections on bridges of the middle ring according to the present disclosure;

FIGS. 10A and 10B are top and bottom perspective views of an example of the moving ring according to the present disclosure;

FIGS. 10C to 10F are cross-sectional views of examples of the moving ring taken along various cross-sections shown in FIG. 10A according to the present disclosure;

FIG. 10G is a top perspective view of an example of two of the N upper portions of the moving ring according to the present disclosure;

FIG. 10H is a bottom perspective view of an example of the moving ring at the projection according to the present disclosure;

FIGS. 11A and 11B are top and bottom perspective views of an example of the static ring according to the present disclosure;

FIGS. 11C to 11F are cross-sectional views of examples of the static ring taken along various cross-sections shown in FIGS. 11A and 11B according to the present disclosure;

FIG. 11G is a top perspective view of an example of a first cavity of the static ring according to the present disclosure;

FIG. 11H is a top perspective view of an example of a second cavity of the static ring according to the present disclosure;

FIGS. 12A and 12B are a top perspective view and a plan view of an example of the bottom edge ring according to the present disclosure; and

FIGS. 12C to 12F are cross-sectional views of examples of the bottom edge ring taken along various cross-sections shown in FIGS. 12A and 11B according to the present disclosure.

In the drawings, reference numbers may be reused to identify similar and/or identical elements.

### DETAILED DESCRIPTION

During substrate processing, a substrate is arranged on a pedestal such as an electrostatic chuck (ESC), process gases are supplied, and plasma is struck in the processing chamber. In some examples, an edge ring is arranged around a radially outer edge of the substrate to shape the plasma. During operation, the substrate and an exposed surface of the edge ring are etched by the plasma. As a result, the edge ring wears and the effect of the edge ring on the plasma changes, which may adversely affect uniformity. For example, due to wear, the exposed surface of the edge ring may have a different height relative to the substrate. Therefore, in some substrate processing systems, the worn edge ring is replaced periodically.

In some embodiments, the edge ring may correspond to a top edge ring in an edge ring system or assembly that further includes a bottom ring and/or a middle ring. For example, the edge ring may be supported on a middle ring or bottom ring. In some embodiments, the edge ring is configured to be transferred into and out of the processing chamber through a same opening (e.g., a slot valve) as substrates. This approach reduces chamber down time by eliminating vacuum break and potential sources of contamination. In systems that include a middle ring, the edge ring may be transferred (e.g., under vacuum, using a transfer robot) together with the middle ring and/or placed onto the middle ring within the processing chamber.

The edge ring may be centered relative to the middle ring to ensure centering relative to the substrate. For example, processing accuracy may be dependent upon a concentric relationship between the edge ring and the substrate. In some embodiments, the edge ring and middle ring are centered by hand (e.g., using shims). In embodiments where the edge ring is transferred using a transfer robot, accurate centering is dependent upon the transfer robot's placement accuracy and manufacturing tolerances of various components and gaps. When an edge ring (e.g., a top edge ring) and middle ring are transferred as a single unit, the edge ring may shift relative to the middle ring during the transfer and/or placement (e.g., due to vibration of the robot). Embodiments of the present disclosure reduce/minimize edge ring shifting during robotic transfer and optimize edge ring centering.

Self-centering edge ring systems and methods according to the present disclosure improve alignment and centering of the edge ring and the middle ring under vacuum. In one embodiment, an outer diameter of a lower surface of the edge ring has a chamfer that contacts the middle ring. In other words, a lower surface of the edge ring is conical. Conversely, an upper surface on the middle ring may have a chamfer that contacts the chamfer of the edge ring (i.e., at least a portion of the upper surface of the middle ring may be conical). The chamfered surfaces maintain the concentricity of the edge ring relative to the middle ring during transfer and placement. For example, the downward force of the chamfer of the edge ring against the middle ring mechanically resists displacement caused by vibration and other lateral forces.

When the edge ring and middle ring are lowered onto the substrate support, the edge ring may be supported on another ring (e.g., an inner or bottom ring) and does not contact the middle ring. Subsequent to placement, the edge ring and the middle ring may be independently raised and lowered. In some embodiments, the edge ring may be periodically re-centered by raising the middle ring (or lowering the edge ring) to cause the middle ring to contact the edge ring. The complementary conical surfaces of the middle ring and the edge ring and the upward force of the raised middle ring force the edge ring into a centered concentric position relative to the middle ring.

Aligning the edge ring to the middle ring in this manner centers the edge ring relative to the substrate support and, therefore, to the substrate arranged on the substrate support. For example, aligning the edge ring to the middle ring using the complementary conical surfaces causes a substantially concentric relationship between the edge ring and the middle ring and between the edge ring and the substrate.

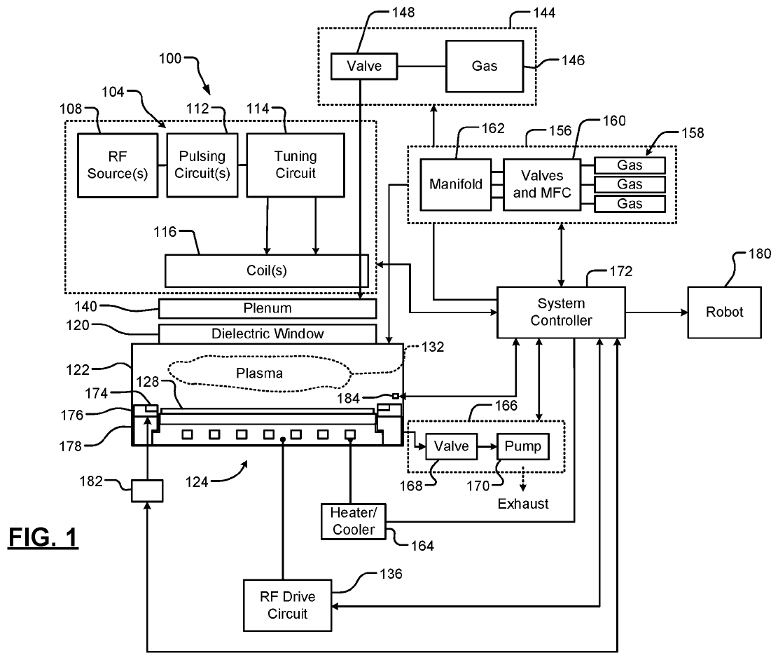

Referring now to FIG. 1, an example of a substrate processing system 100 that performs plasma processing and that includes a replaceable edge ring system according to certain embodiments of the present disclosure is shown. The substrate processing system 100 includes a coil driving circuit 104. In some examples, the coil driving circuit 104 includes an RF source 108, a pulsing circuit 112, and a tuning circuit 114. The pulsing circuit 112 controls a TCP envelope of the RF signal and varies a duty cycle of the TCP envelope (e.g., between 1% and 99%) during operation. As can be appreciated, the pulsing circuit 112 and the RF source 108 can be combined or separate.

The tuning circuit 114 may be directly connected to one or more inductive coils 116. The tuning circuit 114 tunes an output of the RF source 108 to a desired frequency and/or a desired phase, matches an impedance of the inductive coils 116 and/or splits power between the inductive coils 116. While examples including multiple coils are shown, a single coil including a single conductor or multiple conductors can be used.

A dielectric window 120 is arranged along one side of a processing chamber 122. The processing chamber 122 further comprises a substrate support (or pedestal) 124 to support a substrate 128. The substrate support 124 may include an electrostatic chuck (ESC), a mechanical chuck or other type of chuck. Process gas is supplied to the processing chamber 122 and plasma 132 is generated inside of the processing chamber 122. An RF bias drive circuit 136 may be used to supply an RF bias to the substrate support 124 during operation to control ion energy. The RF bias drive circuit 136 may include an RF source and an impedance matching circuit (not shown).

In some embodiments, a plenum 140 is arranged adjacent to (e.g., above, as shown) the dielectric window 120. A gas delivery system 144 may be used to deliver gas from a gas source 146 via a valve 148 to the plenum 140. The gas may include cooling gas (air) that is used to cool the inductive coils 116 and the dielectric window 120.

A gas delivery system 156 may be used to supply a process gas mixture to the processing chamber 122. The gas delivery system 156 may include gas sources 158 (e.g., precursor, vapor, one or more other gases, inert gases), a gas metering system 160 such as valves and mass flow controllers, and a manifold 162. A gas injector (not shown) may be arranged at a center of the dielectric window 120 (or other location) and is used to inject gas mixtures from the gas delivery system 156 into the processing chamber 122.

A heater/cooler 164 may be used to heat/cool the substrate support 124 to a predetermined temperature. An exhaust system 166 includes a valve 168 and pump 170 to control pressure in the processing chamber 122 and/or to remove reactants from the processing chamber 122 by purging or evacuation.

A system controller 172 may be used to control the process. The system controller 172 monitors system parameters and controls delivery of the gas mixtures, striking, maintaining and extinguishing the plasma, removal of reactants, supply of cooling gas, etc.

The substrate support 124 may include an edge ring assembly or system including a top edge ring 174. As shown, the top edge ring 174 is arranged above a middle ring 176 and a bottom ring 178. As described below in more detail, an outer diameter of a lower surface of the top edge ring 174 may have a chamfer that contacts the middle ring 176 during transfer. Correspondingly, an upper surface on the middle ring may have a chamfer that contacts the chamfer of the edge ring during transfer. The chamfered surfaces maintain the concentricity of the top edge ring 174 relative to the middle ring 176 during transfer and placement.

For example, the system controller 172 controls a robot 180 to deliver substrates and/or edge rings to the processing chamber 122. The system controller 172 also controls one or more actuators 182 that move lift pins (not shown in FIG. 1) to selectively raise and lower the top edge ring 174 and/or the middle ring 176 to facilitate transfer of the top edge ring 174 to and from the substrate support 124. When the top edge ring 174 and middle ring 176 are lowered onto the substrate support 124, the top edge ring 174 may be supported on the bottom ring 178 and does not contact the middle ring 176. In other words, lowering the top edge ring 174 and the middle ring 176 causes the bottom ring 178 to contact the top edge ring 174 and separate the top edge ring 174 from the middle ring 176. Although shown as a single ring, in some embodiments the bottom ring 178 may include two or more concentric rings, such as an outer bottom ring (e.g., a static ring configured to support the middle ring 176) and an inner ring (e.g., a moving or lifter ring configured to raise and lower the top edge ring 174).

The system controller 172 may also receive outputs from one or more sensors 184 that are used to sense a height of the edge rings. Non-limiting examples of sensors include optical sensors, physical sensors, piezo sensors, ultrasonic sensors, etc.

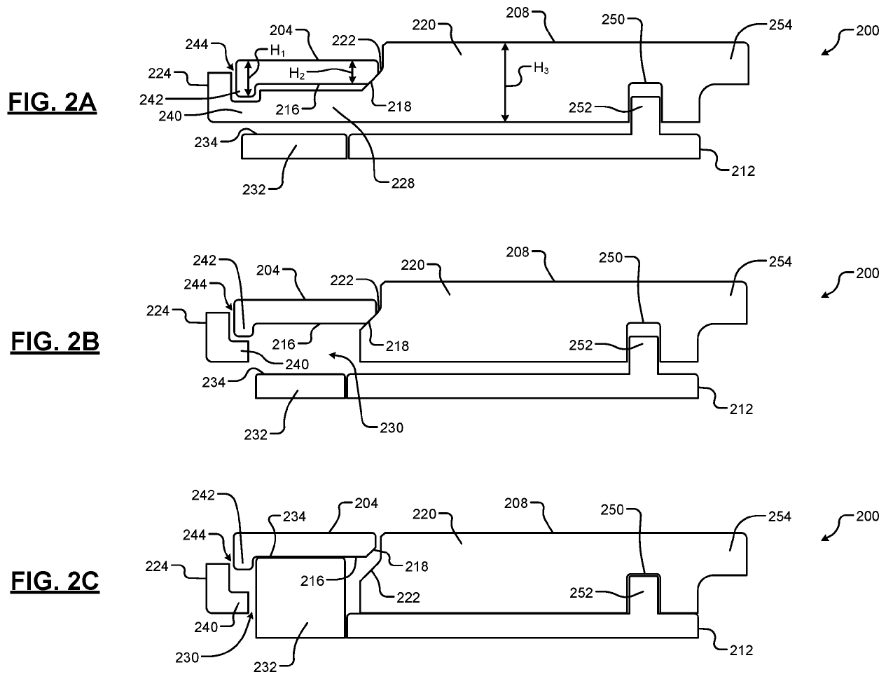

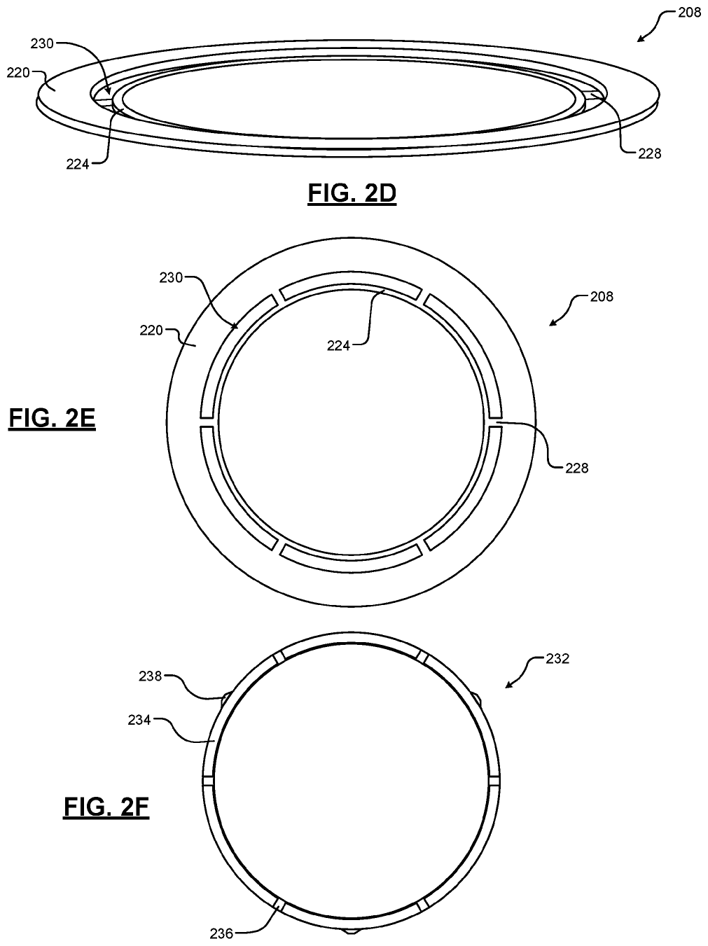

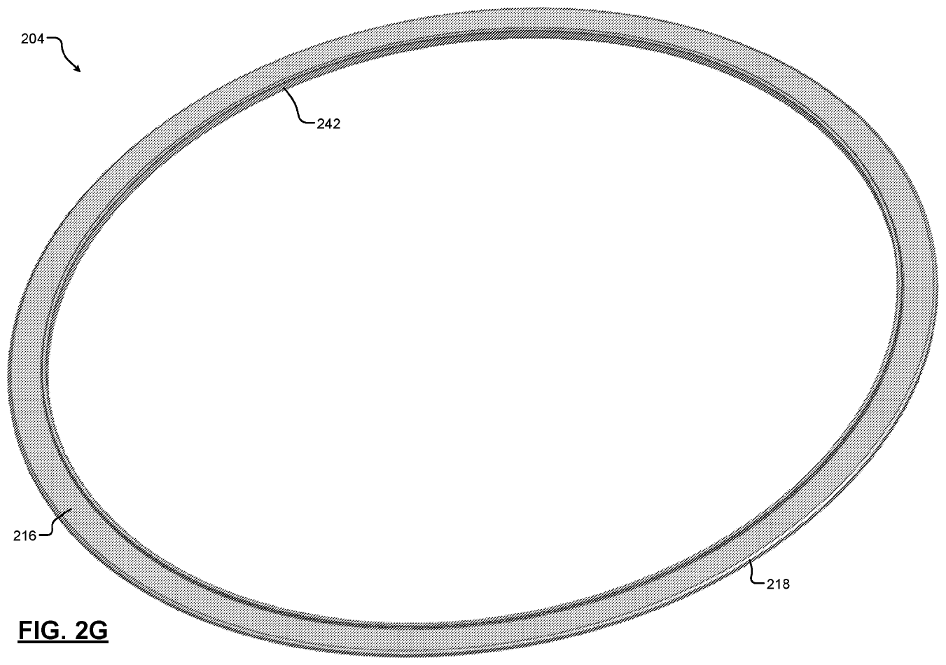

An edge ring system 200 including an edge ring 204 and a middle ring 208 is shown in cross-section in FIGS. 2A, 2B, and 2C and an isometric view of the middle ring 208 is shown in FIG. 2D. A plan view of the middle ring 208 is shown in FIG. 2E. A plan view of a moving ring 232 is shown in FIG. 2F. Isometric views of a bottom of the edge ring 204 are shown in FIGS. 2G and 2H. As shown in FIGS. 2A and 2B, the edge ring 204 is supported on the middle ring 208 during transfer (i.e., during transfer to the substrate support 124 and prior to placement on a bottom ring 212).

An outer diameter of a lower surface 216 of the edge ring 204 has a chamfer 218 (i.e., a downward and outward facing chamfered surface) that contacts and is supported on the middle ring 208 during transfer. In other words, the lower surface 216 of the edge ring 204 is conical. An inner diameter of an outer ring portion 220 of the middle ring 208 may have a complementary chamfer 222 (i.e., an upward and inward facing chamfered surface) that contacts the chamfer 218 of the edge ring 204 (i.e., at least a portion of the upper surface of the middle ring 208 may be conical). In other words, the inner diameter of the outer ring portion 220 has a chamfered corner (or a sloped surface) positioned between a top surface of the bridge 228 and the inner diameter surface of the outer ring portion 220. In some embodiments, the chamfer 222 may be larger than a corner such that the slope surface may extend from a top surface of the bridge 228 to a top surface of the outer ring portion 220. The chamfers 218 and 222 maintain the concentricity of the edge ring 204 relative to the middle ring 208 during transfer and placement.

As shown in FIGS. 2D and 2E, the middle ring 208 includes the outer ring portion 220 and an inner ring portion 224. The inner ring portion 224 is coupled to the outer ring portion 220 via a two or more bridges 228. FIG. 2A is a cross-sectional view taken at a location of one of the bridges 228. Conversely, FIG. 2B is a cross-sectional view taken at a location of one of a plurality of gaps 230 between the bridges 228. As shown, the edge ring 204 does not contact the bridges 228 during transfer.

While only two of the bridges 228 are visible in FIG. 2D, the middle ring 208 may include any number of bridges. In some embodiments, the middle ring 208 has six or more bridges 228. In some embodiments, each bridge has a width of about 8-12 mm. The width of the bridges 228 may vary with the number of bridges. As the number of bridges 228 increases, the widths of the bridges 228 may decrease and vice versa. In this manner, an overall area of the gaps 230 may be maintained at desired value. For example, during processing, the edge ring 204 is raised by and supported on a moving ring 232. In some embodiments, all of the bridges 228 have the same width (or substantially the same width). In some embodiments, a subset of bridges 228 has a different width than another subset of bridges 228. A subset of bridges may include one or more bridges.

A plan view of the moving ring 232 is shown in FIG. 2F. Raised portions 234 of the moving ring 232 extend through the gaps 230 to contact the edge ring 204. For example, an upper surface of the moving ring 232 includes a plurality of the raised portions 234 alternating with slots or grooves 236. Since FIGS. 2A-2C are cross-section views taken at a location of one of the raised portions 234 with the moving ring in a lowered position (in FIGS. 2A and 2B) and a raised position (FIG. 2C), the grooves 236 are not visible in FIGS. 2A-2C.

Accordingly, the edge ring 204 is capacitively coupled to the moving ring 232. Since the size of the gaps 230 determine a contact surface area between the edge ring 204 and the moving ring 232, the widths of the bridges 228 and the corresponding sizes of the gaps 230 are selected to maximize capacitive coupling between the edge ring 204 and the moving ring 232. In other words, as an overall area of the bridges 228 increases, an overall area of the raised portions 234 decreases and an overall contact surface area between the raised portions 234 and a bottom surface of the edge ring 204 decreases.

Conversely, as an overall area of the bridges 228 decreases, an overall area of the raised portions 234 increases and an overall contact surface area between the raised portions 234 and a bottom surface of the edge ring 204 increases. However, as an overall area (and respective widths) of the bridges 228 decreases, mechanical stability, strength, etc. of the bridges 228 decreases. Accordingly, the overall area and respective widths of the bridges 228 are selected to maximize capacitive coupling between the moving ring 232 while also maintaining mechanical strength of the bridges 228 over a lifetime of the edge ring system 200.

In some embodiments, a contact area of the moving ring 232 (i.e., an overall area of the raised portions 234) contacts about 72-76% of the bottom surface of the edge ring 204. In some embodiments, the contact area is about 74-75% of the bottom surface of the edge ring 204. Conversely, a portion of the bottom surface of the edge ring 204 that does not contact the raised portions 234 overlaps the bridges 228. In some embodiments, about 24-28% of the edge ring 204 overlaps the bridges 228. In some embodiments, the surface area of the edge ring 204 that overlaps the bridges is about 25-26%. In these embodiments, the range ratio of the contact/overlapping area allows sufficient bridge surface area for stable robotic transfer while maximizing the surface contact area of the bottom surface of the edge ring 204 for coupling strength.

In some embodiments, a robot transfer module is configured to contact a portion of the bridge 228 when transferring the edge ring assembly (including the edge ring 204 and the middle ring 208). In some embodiments, the middle ring is configured with fewer bridges (less than 6 as shown in FIG. 2E, but greater than 2 bridges), so that the contact surface percentage of the moving ring 232 and the bottom surface of the edge ring 204 would increase beyond 76%. However, regardless of the number of the bridges, the bridges are designed to be mechanically stable and support the inner and outer parts of the middle ring at the end of life.

In an embodiment, one or more tabs or bump-outs 238 may extend radially outward from an outer perimeter of the moving ring 232. The bump-outs 238 are aligned with corresponding lift pins (not shown in FIGS. 2A-2F) that extend upward outside of the outer perimeter of the moving ring 232. In this manner, the lift pins raise and lower the moving ring 232, which in turn raises and lowers the edge ring 204.

As shown in FIGS. 2A-2C, the inner ring portion 224 has a generally “L”-shaped cross-section. For example, the inner ring portion 224 has a ledge 240 that extends radially outward toward the outer ring portion 220. Conversely, an inner diameter of the lower surface 216 of the edge ring 204 has a rim 242 that extends downward toward the ledge 240. During transfer, the rim 242 may contact the ledge 240. In other words, the edge ring 204 may be at least partially supported on the inner ring portion 224 during transfer. The edge ring 204 as shown is supported entirely within an inner diameter and an outer diameter of the middle ring 208. In embodiments, the edge ring 204 is partially supported on the ledge 240, the middle ring 208 (e.g., on the chamfer 222), or both the ledge 240 and the middle ring 208. In an embodiment, the edge ring 204 is supported only on the ledge 240.

In some embodiments, one or both of the chamfers 218 and 222 may be omitted. For example, the inner ring portion 224 and the rim 242 may be configured to provide centering functionality. In other words, as shown, engagement between the inner ring portion 224 and the rim 242 prevents lateral movement of the edge ring 204 relative to the middle ring 208. Further, in the raised position shown in FIG. 2C, the rim 242 extends downward below a plane defined by an upper end of the inner ring portion 224. In other words, an interface 244 between the edge ring 204 and the inner ring portion 224, the bridges 228, and the moving ring 232 defines a serpentine path. Accordingly, direct line-of-sight between a plasma volume above the edge ring system 200 and a lower surface of the rim 242, the ledge 240, the bridges 228, and an inner diameter of the moving ring 232 is interrupted. In addition to protecting portions of the middle ring 208 and the moving ring 232 from direct exposure to the processing environment, the rim 242 also improves capacitive coupling between edge ring 204 and the moving ring 232.

In embodiments, a thickness or height H₁ of the edge ring 204 at an inner diameter (i.e., at a location corresponding to the rim 242) is 3.0 to 4.0 mm. In one embodiment, the height H₁ is about (e.g., within +/−5% of) 3.5 mm. A thickness or height H₂ of the edge ring 204 at a location radially outward of the rim 242 is 2.0 to 2.5 mm. In one embodiment, the height H₂ is about (e.g., within +/−5% of) 2.2 mm. In one embodiment, H₂ is about (e.g., within +/−5% of) 62% of H₁. A maximum thickness or height H₃ of the middle ring is between 7.0 and 8.0 mm. In one embodiment, the height H₃ is about (e.g., within +/−5% of) 7.5 mm and is greater than twice H₁. In one embodiment, the height H₃ is about (e.g., within +/−5% of) 210% of H₁.

In some embodiments, the middle ring 208 and/or the bottom ring 212 includes one or more centering or alignment features. As shown, an annular groove 250 is defined in a lower surface of the middle ring 208 and an annular rim 252 extends upward from an upper surface of the bottom ring 212. The annular groove 250 is configured to receive the annular rim 252 when the middle ring 208 is lowered onto the bottom ring 212. The annular groove 250 and the annular rim 252 create a serpentine path between the middle ring 208 and the bottom ring 212 to interrupt direct line-of-sight. In this manner, plasma and other process materials are prevented from penetrating between the middle ring 208 and the bottom ring 212.

In some embodiments, an outer diameter of the middle ring 208 includes a projection 254 that extends radially outward from the middle ring 208. The projection 254 is configured to extend above one or more other structures of the processing chamber (e.g., an upper end of a chamber liner, not shown) to protect the structures from erosion caused by exposure to plasma.

In an embodiment, the bottom ring 212 is configured to encircle the moving ring 232, which in turn encircles an ESC (e.g., the substrate support 124). The moving ring 232 may be supported on the substrate support 124. In an embodiment, the raised portions 234 on an upper surface of the moving ring 232 are aligned with the gaps 230 between the bridges 228 of the middle ring 208. Conversely, the grooves 236 between the raised portions 234 are aligned with the bridges 228. Accordingly, when the moving ring 232 is raised, the raised portions 234 pass through the gaps 230 to contact the edge ring 204. In this manner, when centered, the edge ring 204 is supported within an inner diameter and an outer diameter of the middle ring 208 while still being moveable (i.e., configured to be raised and lowered) by the moving ring 232 located below the middle ring 208.

Further, when the edge ring 204 is in a raised position during processing (as shown in FIG. 2C), the edge ring 204 may be periodically (e.g., between processes or processing steps) re-centered by lowering the moving ring portion 232-1 to cause the chamfer 218 to contact the chamfer 222. In some embodiments, the middle ring 208 can instead be raised to cause the chamfer 222 to contact the chamfer 218. In either example, contact between the chamfers 218 and 222 (and/or between the ledge 240 and the rim 242) force the edge ring 204 into a centered concentric position relative to the middle ring 208.

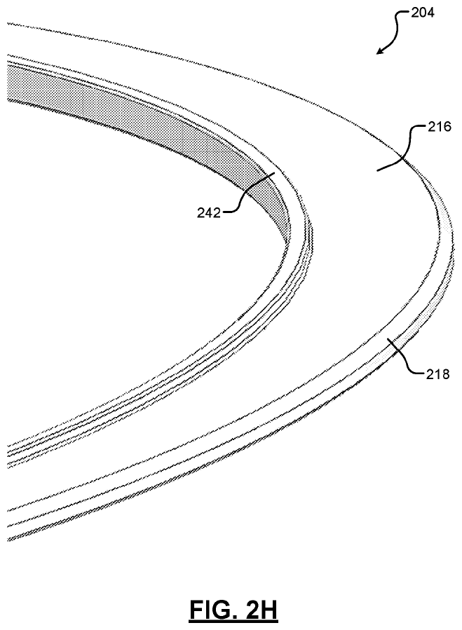

FIGS. 3A and 3B show first and second cross-sectional views of an edge ring system 300 including an edge ring 304, a middle ring 308, a bottom ring 312, and a moving ring assembly 316. The moving ring assembly 316 includes a moving ring portion 316-1 and a static ring portion 316-2 (referred to collectively as moving ring assembly 316). The static ring portion 316-2 is supported on an outer ring portion of an ESC 320. A lift pin 324 shown in FIG. 3A extends through the ESC 320 to engage the moving ring portion 316-1. FIG. 3A is a cross-sectional view of the edge ring system 300 taken at a location of the lift pin 324. For example, the lift pin 324 engages a bump-out 326 that extends radially outward from an outer perimeter of the moving ring portion 316-1. Accordingly, the moving ring portion 316-1 is raised and lowered by raising and lowering the lift pin 324.

For example, a controller (e.g., the system controller 172) is configured to control an actuator to raise and lower the lift pin 324 to raise and lower the moving ring portion 316-1, which in turn raises and lowers the edge ring 304. The moving ring portion 316-1 may be raised to raise the edge ring 304 to a desired height during processing. In some embodiments, the position of the edge ring 304 can be adjusted during processing, between processing steps, etc. to fine tune processing performance. Conversely, the moving ring portion 316-1 is lowered to lower the edge ring 304 to re-center the edge ring 304 as described above, or to place the edge ring 304 on the middle ring 308 for transfer, etc.

Similarly, a lift pin 328 shown in FIG. 3B (e.g., a cross-sectional view taken at a location of the lift pin 328) extends through the bottom ring 312 to engage the middle ring 308. FIG. 3B is a cross-sectional view of the edge ring system 300 taken at a location of the lift pin 328. The system controller 172 is configured to control an actuator to raise and lower the lift pin 328 to raise and lower the middle ring 308. For example, the middle ring 308 may be raised, along with the edge ring 304, to facilitate removal of the middle ring 308 and the edge ring 304 by a robot.

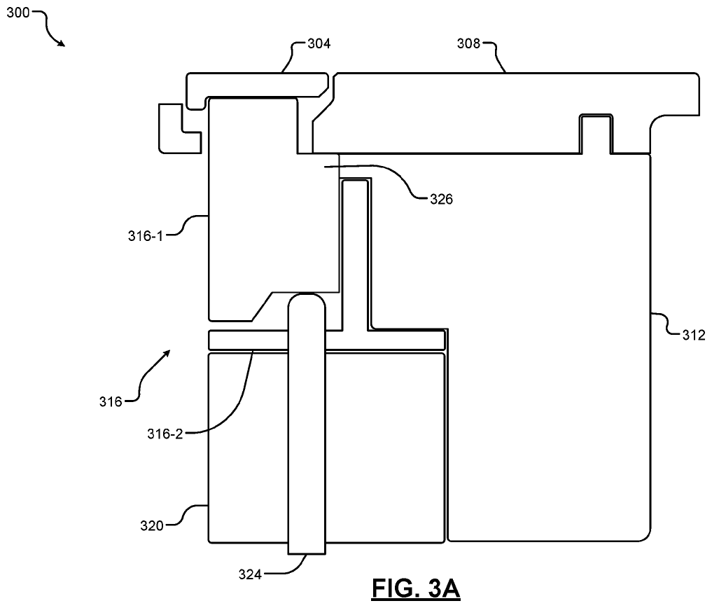

Referring now to FIGS. 4A and 4BS, an edge ring system 400 is arranged around a substrate support including a baseplate 410 and a top plate 412. A substrate 414 is arranged on the top plate 412 during processing. A static ring 420 is arranged radially outside of the baseplate 410 and on and above a lower projection 413 of the baseplate 410 that extends radially outwardly. The static ring 420 includes an annular body and a radially inward projection 424.

A bottom edge ring 430 includes an annular body that is arranged radially outside of and extends below the static ring 420. The bottom edge ring 430 includes a radially inward annular rim 432 extending from an upper surface of an annular body of the bottom edge ring 430. The bottom edge ring 430 includes an annular rim 434 extending upwardly from an upper surface of the annular body of the bottom edge ring 430. In some examples, the static ring 420 is arranged around the baseplate 410 prior to installing the bottom edge ring 430. A lower surface of the radially inward annular rim 432 rests on an upper surface and contacts the upper surface of the static ring 420 when installed.

A middle ring 440 includes an annular body with an outer ring portion 442 and an inner ring portion 444. A bottom surface of the outer ring portion 442 includes an annular groove 446 configured to receive and interface with the annular rim 434. The annular groove 446 and the annular rim 434 define a tortuous path. The tortuous path reduces arcing by preventing direct line of sight between the plasma and conducting components of the baseplate. The tortuous path may also reduce entry of particles that occur when arcing occurs.

In some examples, an annular cavity 449 is located below a lower and radially outer portion of the middle ring 440. A radially outer edge 441 of the middle ring 440 extends over a radially outer edge 433 of the bottom edge ring 430. The overlap provided by the radially outer edge 441 reduces erosion of the bottom edge ring 430, which reduces particle generation and wear of the bottom edge ring. The annular cavity 449 reduces a vertical height of the middle ring 440 to allow clearance for other equipment in the processing chamber located radially outside of the middle ring 440 and the bottom edge ring 430.

The outer ring portion 442 defines an annular cavity 447 on an upper and radially inner surface thereof to receive a cover ring 470 as will be described further below. The outer ring portion 442 includes a radial projection 448 that extends radially inwardly and that is connected by bridges to the inner ring portion 444 as will be described further below. In some examples, the inner ring portion 442 has an “L”-shaped cross-section.

A top edge ring 450 is arranged above a moving ring 460. In some examples, the top edge ring 450 includes an annular body and has a “C”-shaped cross-section. The top edge ring 450 defines a cavity 456 on a bottom surface thereof between an outer annular projection 452 and an inner annular projection 454 that extend in an axial or downward direction towards the moving ring 460. At this radial location, the moving ring 460 has a “T”-shaped cross-section. The moving ring 460 includes one or more (N) upper portions 462 having an arcuate shape and a lower annular portion 464 where N is an integer greater than zero. The N upper portions 462 are located between the inner ring portion 444 of the middle ring 440 and the radial projection 448 of the middle ring 440 and below and/or inside of the cavity 456 of the top edge ring 450.

A cover ring 470 is arranged above the radial projection 448 of the middle ring 440 and between the top edge ring 450 and a radially inner surface of the outer ring portion 442 of the middle ring (e.g., in the annular cavity 447 of the middle ring 440). In some examples, the cover ring 470 has an inverted “L”-shaped cross-section. In some examples, a radially inner surface 472 of the cover ring 470 is located along the same vertical plane (when viewed from top) or radially inward of a radially outer edge of the N upper portions 462 of the moving ring to prevent direct line of sight to the plasma. An arcuate surface 476 is arranged below the radially inner surface 472 of the cover ring 470. In some examples, an arcuate surface 458 at an upper and radially outer surface of the top edge ring 450 has a similar curvature as the arcuate surface 458 of the top edge ring 450 to allow the top edge ring 450 to move upwardly relative to the cover ring 470 below the radially inner surface 472. In some examples, arcuate surfaces 476 reduce/eliminate the likelihood of arcing between the arcuate surfaces 458 and the cover ring 470.

In FIG. 4A, the top edge ring 450 and the moving ring 460 are shown in a lowered position. In FIG. 4B, the top edge ring 450 and the moving ring 460 are shown in a raised position. The arcuate surface 458 of the top edge ring 450 is nested inside of the arcuate surface 476 of the cover ring 470.

In some examples, a bottom surface of the static ring 420 rests on the lower projection 413 of the baseplate 410. A bottom surface of the radially inward annular rim 432 of the bottom edge ring 430 rests on an upper surface of the static ring 420. A gap is defined between a bottom surface of the middle ring 440 and the upper surface of the bottom edge ring 430. A bottom surface of the top edge ring 450 rests on the N upper portions 462 of the moving ring 460. The top edge ring 450 is spaced from the middle ring 440. A bottom surface of the inner ring portion 444 rests on the top plate 412.

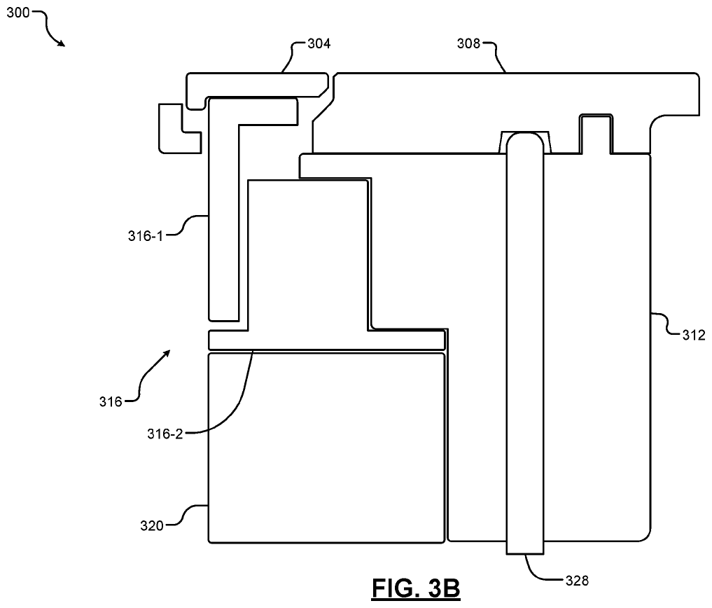

Referring now to FIGS. 5A and 5B, the edge ring system 400 is shown at another radial cross-section. The bottom edge ring 430 includes a bore 510 extending vertically through the annular body of the bottom edge ring 430 and a lift pin 512 arranged in the bore 510. A bottom surface of the outer ring portion 442 of the middle ring 440 includes an alignment portion 518 aligned with the lift pin 512. In some embodiments, alignment portion 518 is positioned in the bottom surface of the middle ring 440 and radially inward from annular groove 446. In some examples, the alignment portion 518 includes a planar surface 521 between opposed inclined surfaces 519 extending in a radial direction to self-center the middle ring 440.

In FIG. 5B, an actuator (not shown) selectively biases the lift pin 512 into the alignment portion 518 to raise the middle ring 440, the top edge ring 450 and the cover ring 470 to allow delivery or replacement of the middle ring 440, the top edge ring 450 and the cover ring 470. A robot may be used to remove the middle ring 440, the top edge ring 450 and the cover ring 470 to/from the processing chamber without opening up the processing chamber. A robot arm may lift all three rings from the bottom surface of the middle ring 440 and transfer (in or out) all three rings at once. The stacking relationship shown in FIG. 5B prevents the top edge ring 450 and cover ring 470 from excessive lateral movements which could allow the rings to drop during transfer. This configuration reduces the time needed to replace this ring assembly (e.g., as compared to transferring each ring one by one), while allowing all three rings to achieve proper alignment upon installation. In some examples, the middle ring 440, the top edge ring 450 and the cover ring 470 withstand over 500 RF hours between replacement. In some examples, the middle ring 440, the top edge ring 450 and the cover ring 470 withstand over 1000 RF hours between replacement.

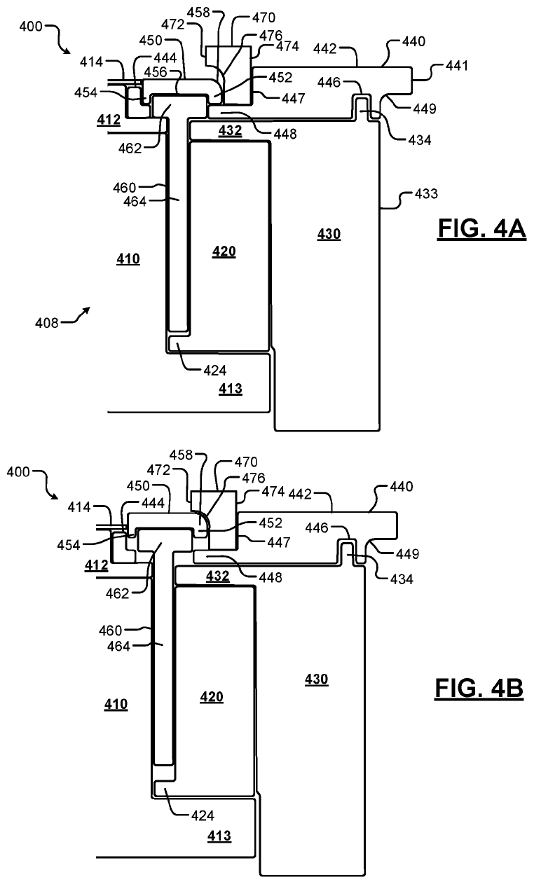

Referring now to FIGS. 6A and 6B, the edge ring system 400 is shown at other radial cross-sections. In FIG. 6A, one of the N bridges 480 of the middle ring 440 is shown. The middle ring 440 includes N bridges 480 extending between the outer ring portion 442 and the inner ring portion 444. The N bridges 480 include an axial projection 482 extending upwardly in an axial direction from the N bridges 480. In some examples, the axial projection 482 is received in the cavity 456 of the top edge ring 450 and facilitates alignment between the top edge ring 450 and the middle ring 440. A gap 483 is defined between a top surface of the axial projection 482 and a bottom surface of the top edge ring 450. The gap 483 ensures that the top edge ring 450 is seated on the N upper portions 462 of the moving ring 460. This ensures that there is electrical contact between the bottom surface of the top edge ring 450 and the top surface of the N upper portions 462 of the moving ring 460. In some examples, the moving ring 460 is made of quartz and is not conductive. The axial projection 482 fills an open space in this region to reduce stray plasma.

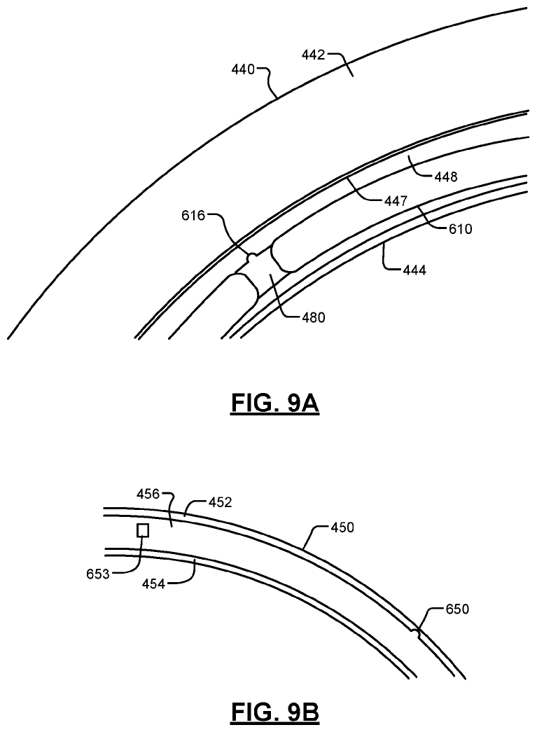

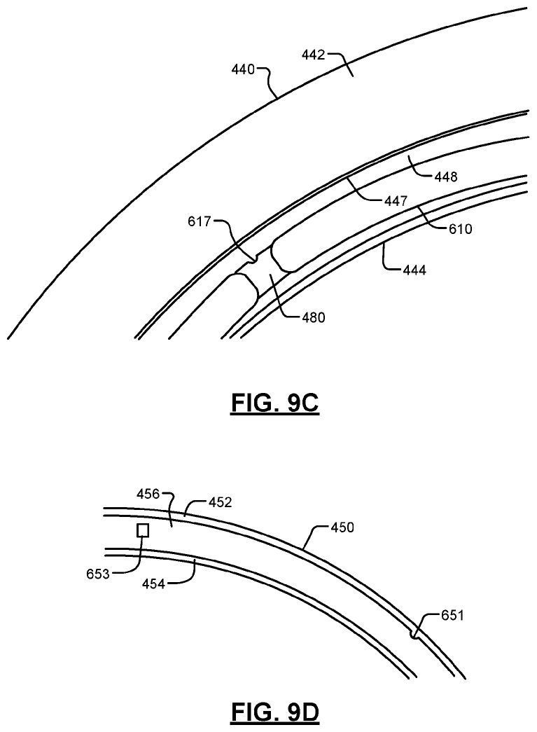

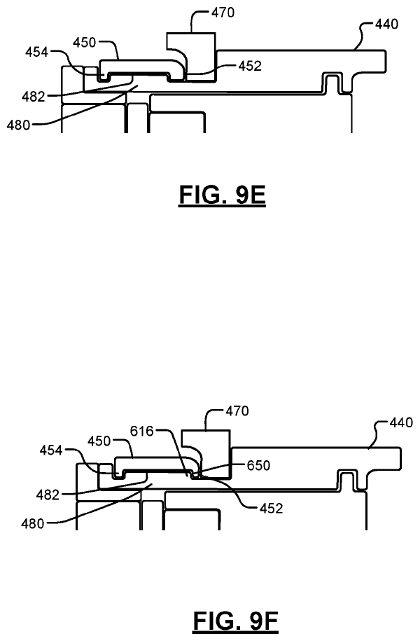

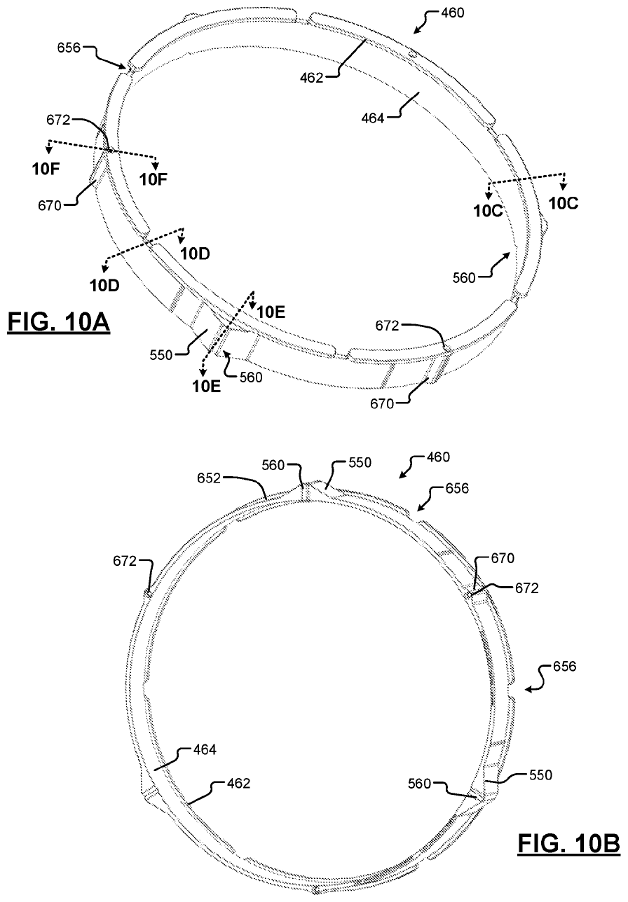

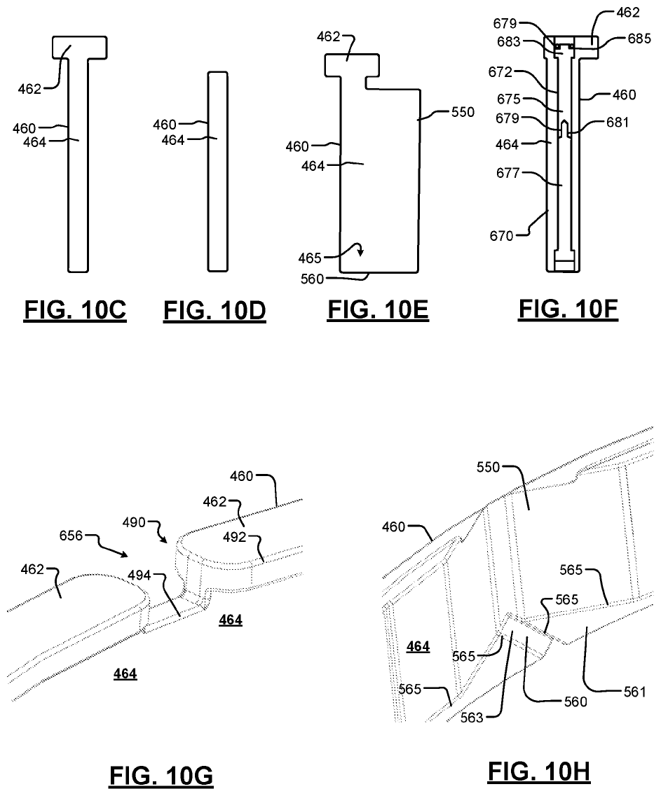

In FIG. 6B, the moving ring 460 includes a gap (shown below in FIGS. 10A and 10B) between the N upper portions 462 and does not include any of the N upper portions 462. The moving ring 460 biases the top edge ring 450 vertically up and down. The lower annular portion 464 of the moving ring 460 moves towards to the N bridges 480 and reduces a gap. In some embodiments, some or all of the N bridges 480 do not include the axial projection 482.

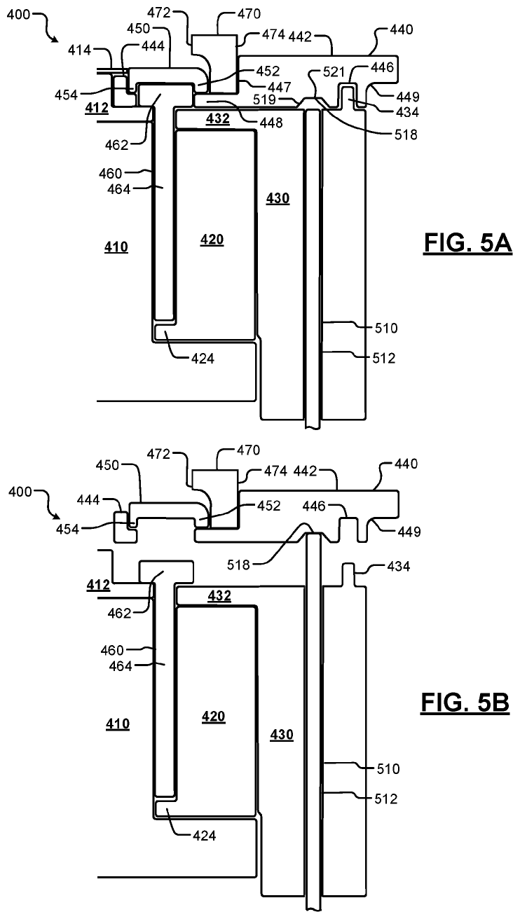

Referring now to FIGS. 7A and 7B, the edge ring system 400 is shown at another radial cross-section. The moving ring 460 includes a projection 550 extending radially outwardly. A self-centering feature (e.g., groove 560) is arranged on a lower surface of the projection 550. In some examples, the groove 560 extends in a radial direction to allow the moving ring 460 to self-align. The radially outward projection 413 of the baseplate 410 defines a vertical bore 574 and the radially inward projection 424 of the static ring 420 defines a bore 576 to receive a lift pin 572. In this radial cross-section, the static ring 420 defines a cavity to receive the projection 550 of the moving ring 460 as will be described further below. In FIG. 7B, the lift pin 572 is biased by an actuator (not shown) into the groove 560 to lift and/or center the moving ring 460 and the top edge ring 450.

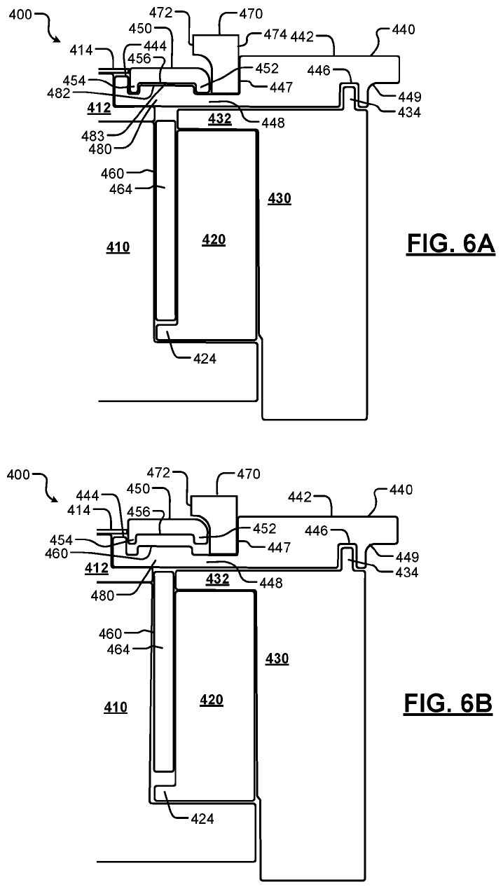

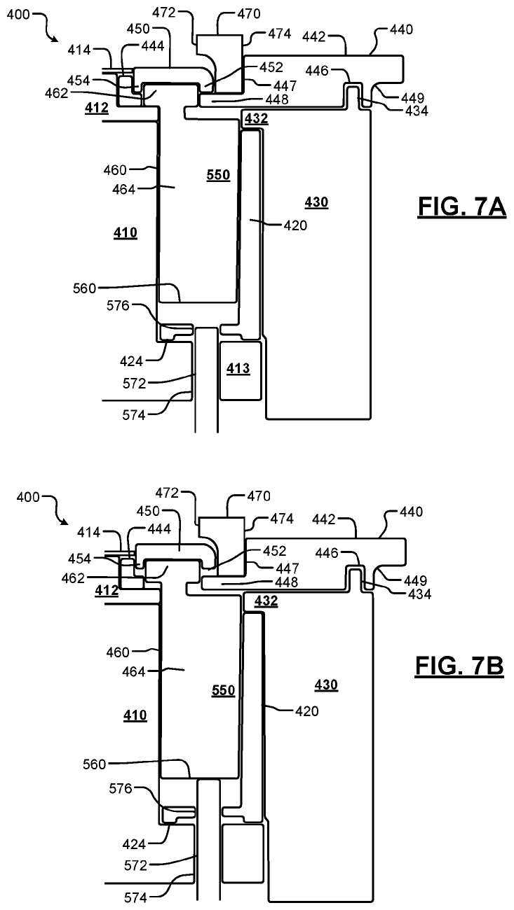

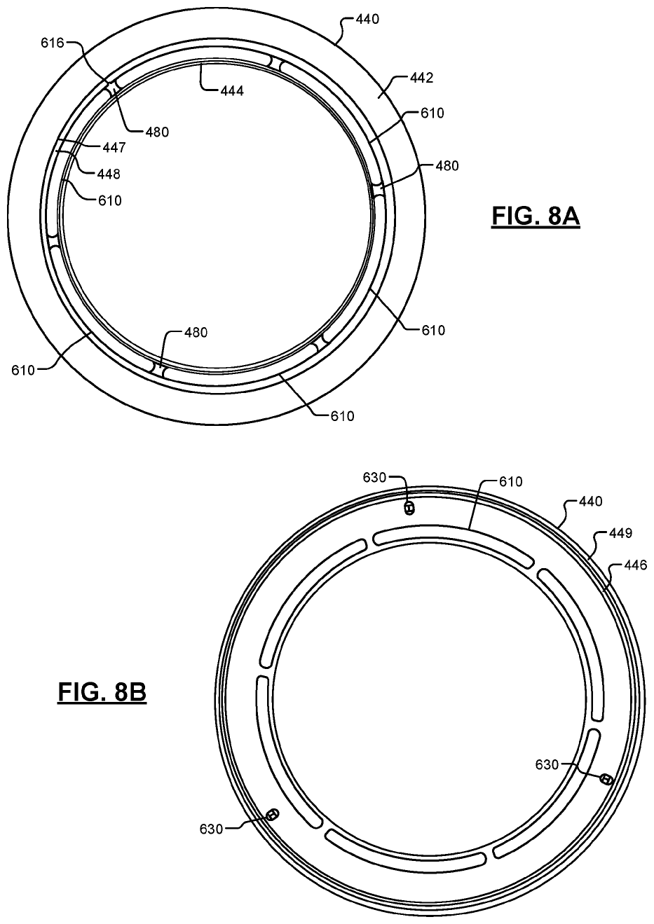

Referring now to FIGS. 8A and 8B, the middle ring 440 is shown in further detail. FIG. 8A illustrates a top view of the middle ring 440 without other rings. The outer ring portion 442 of the middle ring 440 is connected by the N bridges 480 to the inner ring portion 444. In some examples, one or more of the N bridges 480 defines a projection 616 (or slot 617 in FIG. 9C) extending radially outwardly (inwardly) from a radially outer side of the one or more of the N bridges 480. In some examples, the projection 616 and/or the slot 617 are mating surfaces such as a semicircular or rounded triangular convex and concave surfaces.

In some examples, only one of the N bridges 480 includes the projection 616 or slot 617. When assembled with other rings, the top edge ring 450 and the cover ring 470 are arranged between the outer ring portion 442 and the inner ring portion 444 of the middle ring 440. FIG. 8B illustrates a bottom view of the middle ring 440. In FIG. 8B, the bottom surface of the middle ring 440 includes one or more grooves 630 to receive one or more lift pins (such as the lift pins 512 in FIG. 5B). The one or more grooves 630 are located radially inside of the annular groove 446. In some examples, the grooves 630 are “V”-shaped grooves with opposed included surfaces aligned in a radial direction to self-center the middle ring 440.

Referring now to FIGS. 9A to 9D, the top edge ring 450 is angularly positioned or clocked relative to the middle ring 440 during processing. In FIG. 9B, a bottom surface of the top edge ring 450 includes a slot 650 (or projection 651 in FIG. 9D) extending radially outwardly (inwardly) on a radially inner edge of the outer annular projection 452. In FIG. 9A, the projection 616 (or slot 617 in FIG. 9C) on a top surface of the middle ring 440 is received in the slot 650 (or projection 651) on the bottom surface of the top edge ring 450 to properly orient a rotational position of the top edge ring 450 relative to the middle ring 440. The top edge ring 450 is also angularly positioned relative to a ring identifying indicia 653 such as a QR code, radio frequency identification (RFID) code, a bar code, etc. Controlling the rotational position of the top edge ring 450 relative to the ring identifying indicia 653 ensures that thickness measurements are consistently made in the same locations around the top edge ring 450 relative to the processing chamber to allow consistent metrics and/or diagnosis of process issues.

In FIG. 9A, the middle ring 440 includes N arcuate openings 610 to receive the N upper portions 462 of the moving ring 460 as can be seen in FIGS. 10A and 10B below. In some examples N is equal to 6 and/or the N arcuate openings have rounded ends. Rounded ends 463 of the N arcuate openings 610 reduce the chance of interference as the N upper portions 462 of the moving ring 460 move up and down relative to the middle ring 440.

In FIG. 9E, the top edge ring 450 and the middle ring 440 are shown in a radial cross-section located away from the slot 650 on the top edge ring 450 and the projection 616 on the middle ring 440. FIG. 9F shows a radial cross-section passing through the projection 616 on the middle ring 440 and the slot 650 on the top edge ring 450. The combined widths of the axial projection 482 and the projection 616 create a higher local radial width due to the projection 616. The top edge ring 450 creates a locally thinner radial width due to the slot 650.

As can be appreciated, the middle ring 440 can include a slot and the top edge ring 450 can include a projection. While the slot 650 is arranged on the radially inner surface of the outer annular projection 452 of the top edge ring 450, the slot (or the projection) can be arranged on the radially outer surface of the inner annular projection 454. Likewise, while the projection (or the slot) is shown on a radially outer edge of the N bridges 480, the projection can be arranged on a radially inner edge of the N bridges 480.

Referring now to FIGS. 10A and 10B, the moving ring 460 is shown in further detail. In some examples, the moving ring 460 includes the projections 550 that are spaced apart where the number of projections 550 can be presented by “P” and P is an integer greater than two. In some examples, as shown in FIG. 10A, the projections 550 (e.g., P=3) (and the grooves 560) are spaced apart by P/360° (e.g.,) 120° to self-center and/or evenly support the weight of the moving ring 460 as it is biased by the lift pins 572 (as shown in FIG. 7B) to adjust the height of the top edge ring 450 during operation. Likewise, the projections 670 (and the bores 672) are spaced P/360° (where P is the number of the projections 670) to evenly support the moving ring 460 on a rack during coating.

In some examples, the projections 550 have a “V”-shaped cross section extending from a radially outer side of the moving ring 460. The groove 560 is arranged on a bottom surface of the projection 550. In some examples, the groove 560 has a “V”-shape with opposed inclined surfaces that are aligned in a radial direction.

The grooves 560 on the projections 550 enable the moving ring 460 to self-center when vertically moved by the lift pin 572. This self-centering function ensures that the moving ring 460 and the top edge ring 450 are centrally positioned relative to the baseplate 410 and the substrate 414 as the moving ring 460 and the top edge ring 450 are moved. In some examples, the lift pins 572 are cycled up and down to self-center the moving ring 460. In some examples, the N upper portions 462 are arcuate with rounded ends. The rounded ends of the N upper portions 462 reduce binding relative to the middle ring 440 that may occur as the moving ring 460 is moved up and down. Gaps 656 are located between adjacent ones of the N upper portions 462 of the moving ring 460.

In some examples, a radially outer surface of the moving ring 460 includes projections 670 and a bore 672 extending through the projections 670 from a top surface of the moving ring 460 (e.g., on some of the N upper portions 462) to a bottom surface of the moving ring 460. In some examples, the bore 672 is used for mounting the moving ring 460 on a rack during coating of the moving ring 460 during manufacturing and prior to use. In other words, during coating of the moving ring 460, the bore 672 receives pins or another type of fastener to position and hold the moving ring 460 on the rack while minimizing external surface area of the moving ring 460 that would be blocked during coating if the bores 672 were not present. In some examples, after coating of the moving ring 460 is completed, the bore 672 is filled with a plug (shown in FIG. 10F). In some embodiments, the moving ring 460 does not have the bores 672 and the coating may be done using a conventional method.

In some examples, the additional material used in the projections 550 and 670 increase the structural strength of the rings to withstand lifting weight, thermal cycling and/or breakage during installation or use relative to the moving ring 460 that do not include the projections 550 and 670.

Referring now to FIGS. 10C to 10F, cross-sectional views of examples of the moving ring 460 taken along various cross-sections shown in FIGS. 10A are shown. In FIG. 10C, the moving ring 460 is shown along cross-sectional line 10C-10C in FIG. 10A. At this location, the moving ring 460 has a “T”-shaped cross section including one of the N upper portions 462 and the annular portion 464 extending from the one of the N upper portions 462.

In FIG. 10D, the moving ring 460 is shown along cross-sectional line 10D-10D in FIG. 10A. At this section, the moving ring 460 has an “I”-shaped cross section including the annular portion 464.

In FIG. 10E, the moving ring 460 is shown along cross-sectional line 10E-10E in FIG. 10A. At this section, the moving ring 460 includes one of the N upper portions 462, the annular portion 464 extending from the one of the N upper portions 462, and the projection 550 extending radially outwardly from the annular portion 464. A bottom facing portion 465 at the projection 550 defines the groove 560, which includes opposed inclined planes extending in a radial direction.

In FIG. 10F, the moving ring 460 is shown along cross-sectional line 10F-10F in FIG. 10A. The moving ring 460 includes one of the N upper portions 462 and the annular portion 464 extending from the one of the N upper portions 462. The projection 670 extends radially outwardly from the annular portion 464. The bore 672 extends through the moving ring 460 and is used for positioning the moving ring 460 on a rack during coating. In some examples, first fasteners 675 and second fasteners 677 are arranged in the bore 672. Ends of the first fastener 675 and the second fastener 677 include mating threaded ends 679 and 681, respectively, that connect the first fastener 675 and the second fastener 677 in the bore 672. An upper, radially outer portion of a head 683 of the first fastener 675 is shown to include an annular cavity 685 to receive an “O”-ring 679 to prevent entry of arcing and/or particles.

Referring now to FIG. 10G, a top perspective view of an example of an adjacent pair of the N upper portions 462 of the moving ring 460 is shown. In some examples, circumferentially facing ends 490 of the N upper portions 462 are rounded to reduce the likelihood of binding as the moving ring 460 is raised and lowered and the N upper portions 462 pass through the N arcuate openings 610 in the middle ring 440. In some examples, edges 492 of the N upper portions 462 and edges 494 in the gaps 656 of the moving ring 460 are chamfered to reduce the likelihood of binding.

Referring now to FIG. 10H, a bottom perspective view of an example of the moving ring 460 is shown at the projection 550. In some examples, the groove 560 is “V”-shaped and includes opposed inclined surfaces 563 extending in a radial direction across a bottom surface 561 of the moving ring 460 to help self-center the moving ring 460 as it is raised and lowered. In some examples, edges 565 are chamfered to reduce the likelihood of binding.

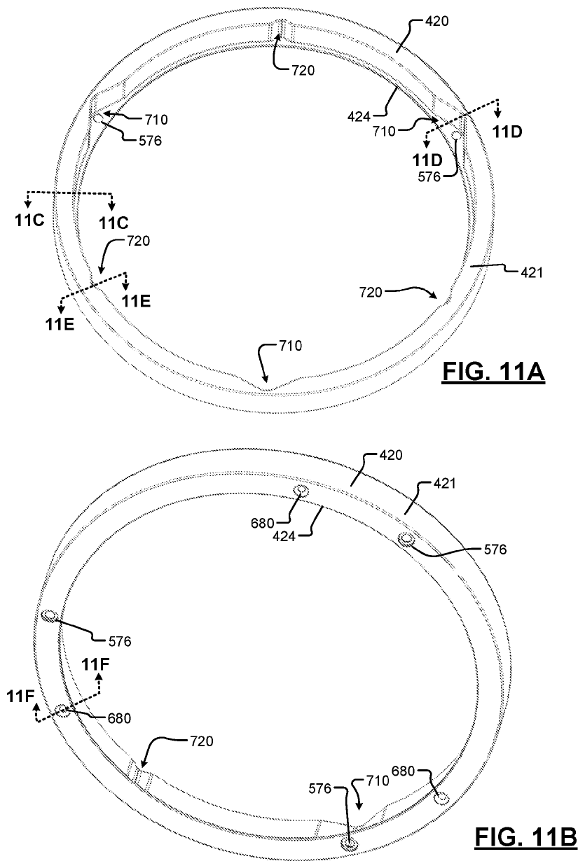

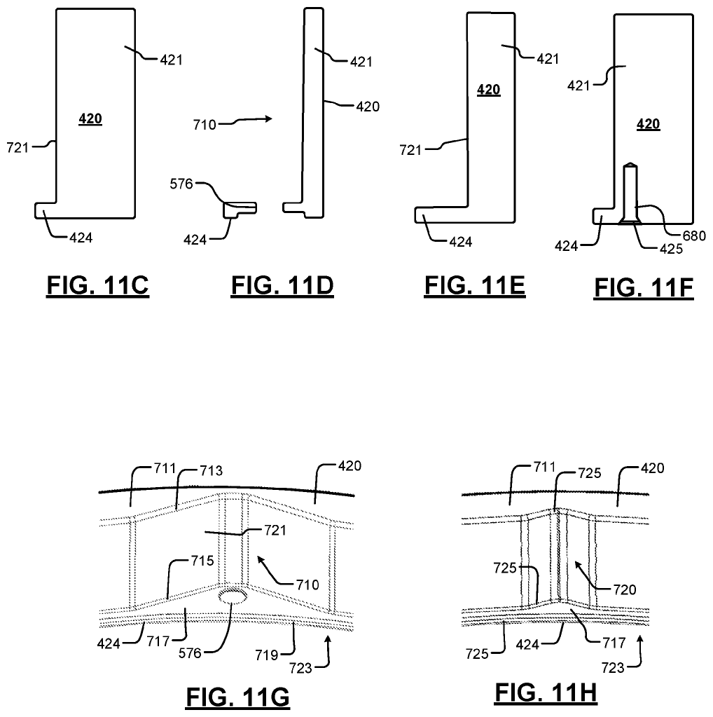

Referring now to FIGS. 11A and 11B, the static ring 420 includes first cavities 710 configured to provide clearance for the projections 550 of the moving ring 460. In some examples, the static ring 420 also includes second cavities 720 configured to provide clearance for the projections 670 of the moving ring 460. In some examples, the first cavities 710 and the second cavities 720 are “V”-shaped. In some examples, the second cavities 720 are spaced at 120° intervals and approximately centered between two of the first cavities 710. The first cavities 710 and the second cavities 720 are spaced at 120° to match the spacing of and provide clearance for the projections 550 and 670 of the moving ring 460, which moves in an axial direction when the top edge ring 450 is biased. In some examples, there are three first cavities 710 and three second cavities 720 and at least one of the three of the first cavities 710 is about 60° from one of the three of the second cavities 720. In examples, each of the three first cavities 710 is about 60° apart from one of the three second cavities 720. Evenly distributing the first cavities 710 and/or second cavities 720 around the perimeter improves even weight distribution of the ring.

In some examples, the static ring 420 further includes one or more bores 680 extending from the bottom surface of the static ring 420 into the annular body in an axial direction. The one or more bores 680 can be used for positioning the static ring 420 on a rack during coating of the static ring 420.

Referring now to FIGS. 11C to 11F, cross-sectional views of examples of the static ring 420 taken along various cross-sections shown in FIGS. 11A and 11B are shown. In FIG. 11C, the static ring 420 is shown along cross-sectional line 11C-11C in FIG. 11A. The static ring 420 includes an annular body 421 and the radially inward projection 424 extending from a side surface 721 of the annular body 421 at a lower edge of the annular body 421.

In FIG. 11D, the static ring 420 is shown along cross-sectional line 11D-11D in FIG. 11A. The static ring 420 includes the annular body 421 that is radially thinner than the cross-section in FIG. 11C due to the first cavity 710 extending radially outwardly into the side surface 721 of the static ring 420. In some examples, the first cavity 710 has a rounded “V”-shape. The radially inward projection 424 extends further from the annular body 421 than the cross-section in FIG. 11C due to the first cavity 710. The bore 576 is formed vertically through the radially inward projection 424 to allow the lift pin 572 to pass through the static ring 420 (FIG. 7B).

In FIG. 11E, the static ring 420 is shown along cross-sectional line 11E-11E in FIG. 11A. The static ring 420 includes the annular body 421 that is radially thinner than the cross-section in FIG. 11C due to the second cavity 720 extending radially outward into the side surface 721 of the static ring 420. In some examples, the second cavity 720 has a rounded “V”-shape. The radially inward projection 424 extends further from the annular body 421 in this location (as compared to FIG. 11C) due to the second cavity 720.

In FIG. 11F, the static ring 420 includes the bore 680 extending into a bottom surface of the annular body 421 to allow the static ring 420 to be supported on a rack during coating of the static ring 420. After coating is complete, the bore 680 can be filled with a plug 425 or other fillers such as a threaded fastener. In some examples, bore 680 is not needed such that FIG. 11F would have a solid body 420 without the bore 680.

Referring now to FIG. 11G, a top perspective view of the first cavity 710 of the static ring 420 is shown. The radial depth of the first cavity 710 provides clearance for the projection 550 of the moving ring 460. In some examples, one or more of edges 713, 715 and 719 between a top surface 711 and a side surface 721, the side surface 721 and a lower surface 717, and the lower surface 717 and a bottom surface 723, respectively, are chamfered to reduce the likelihood of binding when installing and removing the static ring 420.

Referring now to FIG. 11H, a top perspective view the second cavity 720 of the static ring 420 is shown. The radial depth of the second cavity 720 provides clearance for the projection 670 of the moving ring 460. In some examples, the radial depth of the first cavity 710 is greater than the radial depth of the second cavity 720. In some examples, edges 725 are chamfered to reduce the likelihood of binding when installing and removing.

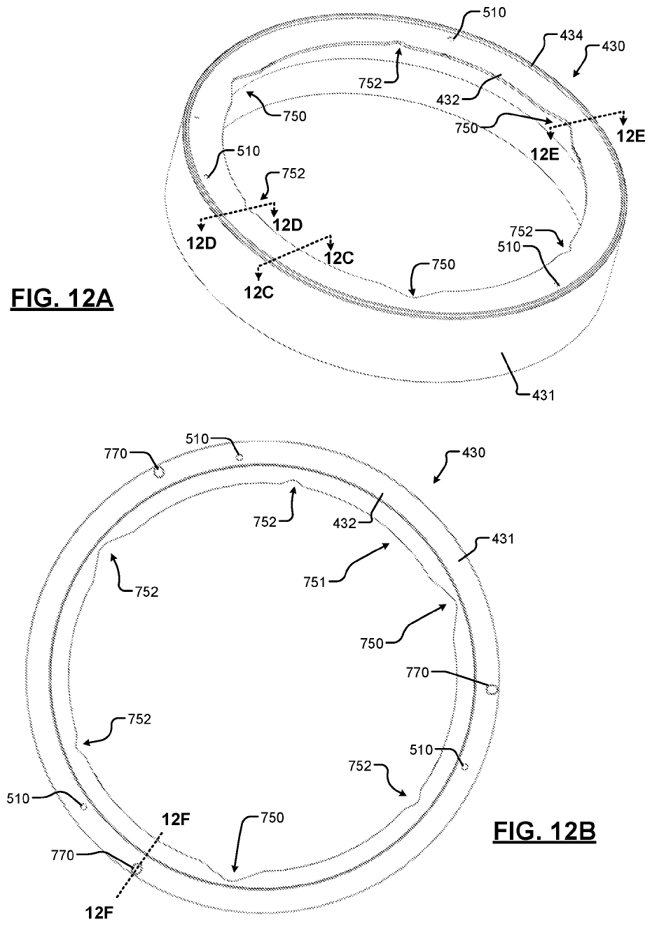

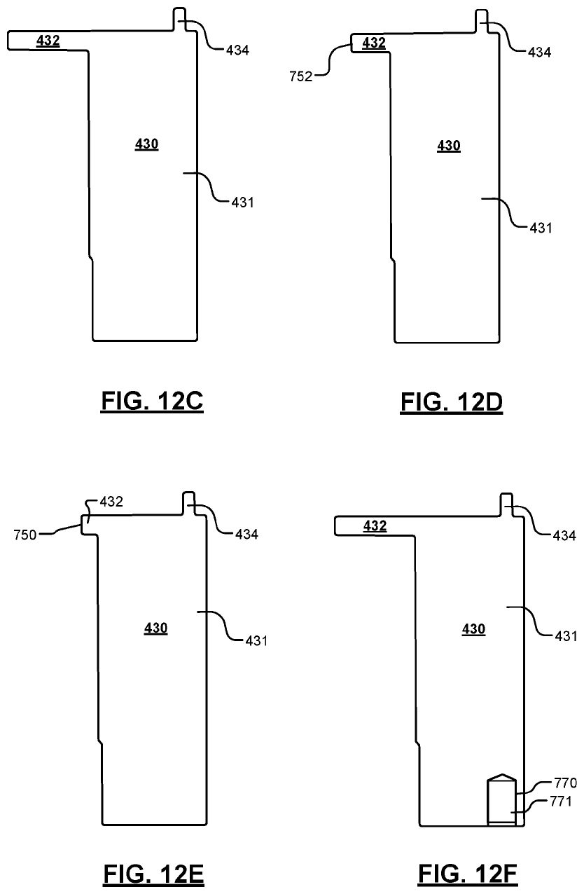

Referring now to FIGS. 12A and 12B, the bottom edge ring 430 includes recesses 750 and 752 in the annular rim 434 that are configured to provide clearance for the projections 550 and 670 of the moving ring 460. In some examples, the locations of the recesses 750 and/or 752 are different than what is depicted depending on the clearance space needed by the moving ring 460. In some examples, the recesses 750 and 752 are “V”-shaped to match a shape of the projections 550 and 670. In some examples, the recesses 752 are spaced at 120° intervals and are approximately centered between the recesses 750 to match a spacing of the projections 550 and 670. In some examples, the bottom edge ring 430 further includes one or more bores 770 extending from the bottom surface of the bottom edge ring 430 into the annular body 431 in an axial direction. The one or more bores 770 can be used to position the bottom edge ring 430 on a rack during coating of the bottom edge ring 430. In some examples, bottom ring 430 does not have the one or more bores 770.

Referring now to FIGS. 12C to 12F, cross-sectional views of examples of the bottom edge ring 430 taken along various cross-sections shown in FIGS. 12A and 12B are shown. In FIG. 12C, the bottom edge ring 430 is shown along cross-sectional line 12C-12C in FIG. 12A. The bottom edge ring 430 includes an annular body 431 and the inward annular rim 432. The inward annular rim 432 is the widest (measured in the horizontal direction) at this location due to the absence of the recesses 750 and 752.

In FIG. 12D, the bottom edge ring 430 is shown along cross-sectional line 12D-12D in FIG. 12A. The bottom edge ring 430 includes the annular body 431 and the inward annular rim 432. The inward annular rim 432 at this location has an intermediate width (as compared to the inward annular rim 432 in FIGS. 12C and 12E) at this location due to the recess 752.

In FIG. 12E, the bottom edge ring 430 is shown along cross-sectional line 12E-12E in FIG. 12A. The bottom edge ring 430 includes the annular body 431 and the inward annular rim 432. The inward annular rim 432 has a narrower width at this location (as compared to FIGS. 12C and 12D) due to the recess 750.

In FIG. 12F, the bottom edge ring 430 is shown along cross-sectional line 12F-12F in FIG. 12B. A bore 770 is used for racking and can be filled by a plug 771 or other fillers such as a fastener after coating. In some examples, bore 770 is not needed such that FIG. 12F would have a solid body 430 without the bore 770.

In some examples, the top edge ring 450 is made of silicon carbide or other plasma resistant material. In some examples, the cover ring 470 and the middle ring 440 are made of quartz or other plasma resistant material. In some examples, the moving ring 460 includes a silicon substrate with aluminum electroplating. In some examples, the static ring 420 is made of a silicon substrate with a coating such as a perfluoroalkoxy alkane (PFA) coating or aluminum electroplating.

In some examples, the top edge ring 450, the cover ring 470, and the middle ring 440 can be removed from the process chamber without opening the processing chamber. In some examples, the top edge ring 450, the cover ring 470, and the middle ring 440 can withstand greater than 500 or 1000 RF hours before replacement is required. The remaining rings including the static ring 420, the moving ring 460, and the bottom edge ring 430 have less exposure to plasma and can last for longer periods. In some examples, the static ring 420, the moving ring 460, and the bottom edge ring 430 have a mean time between cleaning (MBTC) greater than or equal to 1 year.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

1-23. (canceled)

24. An edge ring system for a substrate processing chamber comprising:
a middle ring configured for arrangement around a substrate support and including:
an outer ring portion;
an inner ring portion;
N arcuate openings arranged between the outer ring portion and the inner ring portion, where N is an integer greater than 1;
N bridges connecting the outer ring portion and the inner ring portion between the N arcuate openings; and
an annular cavity arranged on a radially inner surface of the outer ring portion; and
a cover ring arranged in the annular cavity; and
a top edge ring arranged above the middle ring between the cover ring and the inner ring portion and above the N arcuate openings and the N bridges of the middle ring.

25. The edge ring system of claim 24, further comprising:
a moving ring including N upper portions having an arcuate shape configured to align with and pass through the N arcuate openings,
wherein the top edge ring rests on the N upper portions, and
wherein the N upper portions of the moving ring are configured to bias a bottom surface of the top edge ring through the N arcuate openings of the middle ring to raise the top edge ring relative to the cover ring.

26. The edge ring system of claim 25, further comprising:
a first lift pin configured to selectively raise the moving ring and the top edge ring upwardly relative to the cover ring and the middle ring; and
a second lift pin configured to selectively bias the middle ring, the top edge ring, and the cover ring relative to the moving ring.

27. The edge ring system of claim 24, wherein the top edge ring has a “C”-shaped cross-section defining an inner annular projection extending downwardly and an outer annular projection extending downwardly and a cavity arranged between the inner annular projection and the outer annular projection.

28. The edge ring system of claim 24, wherein the N bridges include a projection extending upwardly towards a lower surface of the top edge ring.

29. The edge ring system of claim 25, wherein the cover ring has an inverted “L”-shaped cross-section.

30. The edge ring system of claim 29, wherein a radially inner side of the cover ring includes a radially inner surface and an arcuate surface.

31. The edge ring system of claim 30, wherein the radially inner surface of the cover ring is located radially inwardly from a radially outer surface of an upper portion of the moving ring.

32. The edge ring system of claim 30, wherein a radially outer surface of the top edge ring is arranged below and radially outside of the radially inner surface of the cover ring.

33. The edge ring system of claim 30, wherein an upper and radially outer edge of the top edge ring has an arcuate shape corresponding to the arcuate surface of the cover ring.

34. The edge ring system of claim 27, wherein:
at least one of the N bridges of the middle ring includes one of a projection and a cavity and a radially inner edge of the outer annular projection of the top edge ring includes the other of a cavity and a projection, and
the one of the projection and the cavity of the at least one of the N bridges of the middle ring is received in the other of the cavity and the projection on the radially inner edge of the outer annular projection of the top edge ring.

35. The edge ring system of claim 25, further comprising a static ring configured for arrangement around the substrate support below the middle ring.

36. The edge ring system of claim 35, wherein the static ring includes a projection extending radially inwardly from a lower portion of a radially inner surface of the static ring, wherein the moving ring is arranged above the projection of the static ring and radially inside of the static ring.

37. The edge ring system of claim 35, wherein the moving ring includes a first plurality of projections extending radially outwardly from the moving ring.

38. The edge ring system of claim 37, wherein a bottom surface of the first plurality of projections includes a groove including opposed inclined surfaces extending in a radial direction.

39. The edge ring system of claim 37, wherein the moving ring includes a second plurality of projections extending radially outwardly from the moving ring and a bore extending in an axial direction through the second plurality of projections.

40. The edge ring system of claim 35, wherein the static ring includes a first plurality of cavities extending in a radially inward direction from a radially inner surface of the static ring and configured to provide clearance for a first plurality of projections of the moving ring.

41. The edge ring system of claim 40, wherein the static ring includes a second plurality of cavities extending in a radially inward direction from a radially inner surface of the static ring and configured to provide clearance for a second plurality of projections of the moving ring.

42. The edge ring system of claim 35, further comprising a bottom edge ring including a first annular rim extending inwardly from a radially inner surface of the bottom edge ring and an annular body arranged around the static ring.

43. The edge ring system of claim 42, wherein the bottom edge ring further includes a second annular rim extending upwardly from an upper surface of the bottom edge ring.

44. The edge ring system of claim 43, wherein the middle ring includes an annular groove configured to receive the second annular rim of the bottom edge ring.

45. The edge ring system of claim 42, wherein a gap is defined between a bottom surface of the middle ring and an upper surface of the bottom edge ring.

46. The edge ring system of claim 42, wherein a bottom surface of the first annular rim rests on the static ring.

47. The edge ring system of claim 42, wherein the first annular rim includes a first plurality of recesses extending in a radially inward direction to provide clearance for a first plurality of projections of the moving ring.

48. The edge ring system of claim 42, wherein the first annular rim includes a second plurality of cavities extending in a radially inward direction from a radially inner surface of the static ring and configured to provide clearance for a second plurality of projections of the moving ring.

49. The edge ring system of claim 24, wherein the middle ring comprises quartz.

50. The edge ring system of claim 24, wherein the cover ring comprises quartz.

51. The edge ring system of claim 24, wherein the top edge ring comprises silicon carbide.

52. The edge ring system of claim 25, wherein the moving ring comprises a silicon substrate with an electroplated aluminum outer layer.

53. The edge ring system of claim 35, wherein the static ring comprises a silicon substrate with one of a coating including perfluoroalkoxy alkane (PFA) and an electroplated aluminum outer layer.

54. A middle ring for a substrate processing chamber, comprising:
an outer ring portion;
an inner ring portion;
N bridges connecting the outer ring portion to the inner ring portion, where N is an integer greater than 1; and
N arcuate openings arranged between the N bridges, respectively, and between the outer ring portion and the inner ring portion.

55. The middle ring of claim 54, further comprising an annular cavity arranged on an upper, radially inner surface of the outer ring portion.

56. The middle ring of claim 54, wherein at least one of the N bridges includes one of a projection and a cavity configured to orient the middle ring relative to another edge ring.

57. The middle ring of claim 56, wherein the one of the projection and the cavity is arranged on a radially outer surface of the at least one of the N bridges.

58. The middle ring of claim 54, wherein the middle ring comprises quartz.

59. The middle ring of claim 54, further comprising G alignment portions arranged on a bottom surface of the outer ring portion, where G is an integer greater than two.

60. The middle ring of claim 59, wherein the G alignment portions include a planar surface arranged between opposed inclined surfaces extending in a radial direction.

61. The middle ring of claim 59, wherein the G alignment portions are configured to self-center the middle ring on lift pins.

62. The middle ring of claim 54, wherein opposite ends of the N arcuate openings are rounded.

63. The middle ring of claim 54, wherein circumferential side surfaces of the N bridges are rounded to define rounded ends of the N arcuate openings.

64. The middle ring of claim 54, further comprising an annular groove arranged on a bottom surface of the outer ring portion.

65. The middle ring of claim 54, further comprising:
G alignment portions arranged on a bottom surface of the outer ring portion and including a planar surface arranged between opposed inclined surfaces extending in a radially outward direction, where G is an integer greater than two; and
an annular groove arranged on a bottom surface of the outer ring portion and located radially outside of the G alignment portions.

66. The middle ring of claim 54, wherein the middle ring comprises quartz.

67. A top edge ring for a substrate processing system comprising:
an annular body having a “C”-shaped cross-section;
an inner annular projection extending downwardly from a radially inner surface of the annular body;
an outer annular projection extending downwardly from a radially inner surface of the annular body;
a cavity arranged between the inner annular projection and the outer annular projection; and
a projection arranged on one of
a radially inner surface of the outer annular projection, and
a radially outer surface of the inner annular projection,
wherein the projection is configured to orient the top edge ring relative to another edge ring.

68. The top edge ring of claim 67, wherein the top edge ring comprises silicon carbide.

69. (canceled)

70. The top edge ring of claim 67, wherein the projection has a semicircular shape.

71. The top edge ring of claim 67, further comprising a cavity arranged on one of:
a radially inner surface of the outer annular projection; and
a radially outer surface of the inner annular projection,
wherein the cavity is configured to orient the top edge ring relative to another edge ring.

72. The top edge ring of claim 71, wherein the cavity has a semicircular shape.

73. The top edge ring of claim 67, wherein the top edge ring comprises silicon carbide.

74. A moving ring for a substrate processing system, comprising:
an annular body;
N upper portions arranged on a top edge of the annular body and having an arcuate shape;
N gaps arranged between the N upper portions;
P first projections arranged on a radially outer surface of the annular body, where P is an integer greater than two; and
P grooves arranged on a bottom surface of the P first projections and configured to self-center the moving ring when the P self-centering portions are biased by P lift pins.

75. The moving ring of claim 74, wherein the P first projections have a “V”-shape.

76. The moving ring of claim 74, wherein the P grooves have a “V”-shape including opposed inclined surfaces extending in a radial direction.

77. The moving ring of claim 74, further comprising:
R first projections arranged on an outer surface, where R is an integer greater than two; and
R bores passing through R of the N upper portions and the R first projections.

78. The moving ring of claim 74, wherein the N upper portions are rounded at opposite circumferential ends thereof.

79. The moving ring of claim 74, wherein the moving ring comprises a silicon substrate with an electroplated aluminum outer layer.

80. A static ring for an edge ring system of a substrate processing system, comprising:
an annular body;
an annular rim extending radially inwardly from a lower end of the annular body;
P first cavities arranged on a radially inner surface of the annular body, where P is an integer greater than two; and
P bores passing through the annular rim in the P first cavities.

81. The static ring of claim 80, wherein the P first cavities have a rounded “V”-shape.

82. The static ring of claim 80, further comprising R second cavities arranged on a radially inner surface of the annular body, where R is an integer greater than two.

83. The static ring of claim 82, wherein the R second cavities have a rounded “V”-shape.

84. The static ring of claim 80, wherein P=3 and the P first cavities are spaced at 120° intervals.

85. The static ring of claim 80, further comprising R second cavities arranged on a radially inner surface of the annular body, wherein R is an integer greater than two, and wherein the R second cavities are arranged between the P first cavities.

86. The static ring of claim 85, wherein P=3, R=3, the P first cavities are spaced at 120° intervals, and the R second cavities are spaced at 120° intervals and are evenly spaced between the P first cavities.

87. The static ring of claim 80, further comprising S cavities extending axially into a bottom surface of the annular body, where S is an integer greater than two.

88. The static ring of claim 87, further comprising S plug arranged in the S cavities.

89. The static ring of claim 80, wherein the static ring comprises a silicon substrate with one of a coating including perfluoroalkoxy alkane (PFA) and an electroplated aluminum outer layer.

90. A bottom edge ring for an edge ring system of a substrate processing system, comprising:
an annular body;
an annular rim extending radially inwardly from an upper end of the annular body; and
P first recesses arranged on a radially inner edge of the annular rim, where P is an integer greater than two.

91. The bottom edge ring of claim 90, wherein the P first recesses are spaced 360°/P and have a rounded “V”-shape.

92. The bottom edge ring of claim 90, further comprising R second recesses arranged on the radially inner edge of the annular rim, where R is an integer greater than two.

93. The bottom edge ring of claim 92, wherein the R second recesses are spaced 360°/R and have a rounded “V”-shape.

94. The bottom edge ring of claim 90, wherein P=3 and the P first recesses are spaced at 120° intervals.

95. The bottom edge ring of claim 90, further comprising R second recesses arranged on a radially inner surface of the annular body, where R is an integer greater than two, wherein the R second recesses are arranged between the P first recesses.

96. The bottom edge ring of claim 95, wherein P=3, R=3, the P first recesses are spaced at 120° intervals, and the R second recesses are spaced at 120° intervals and are evenly spaced between the P first recesses.

97. The bottom edge ring of claim 90, further comprising S bores extending axially through the annular body, where S is an integer greater than 2.

98. The bottom edge ring of claim 90, further comprising T bores extending axially into the annular body, where T is an integer greater than 2.

99. The bottom edge ring of claim 98, further comprising T plugs arranged in the T bores.
